(19) United States
(12) Patent Application Publication
(10) Pub. No.: US 2026/0079597 A1
(43) Pub. Date: Mar. 19, 2026

(54) DISPLAY DEVICE

(71) Applicant: LG Display Co., Ltd., Seoul (KR)

(72) Inventors: HoonBae Kim, Paju-si (KR); NamYong Gong, Paju-si (KR); SungChul Kim, Paju-si (KR); SunYeop Kim, Paju-si (KR); Sung-Jin Kang, Paju-si (KR); Jongsung Kim, Paju-si (KR)

(21) Appl. No.: 19/314,114

(22) Filed: Aug. 29, 2025

(30) Foreign Application Priority Data
Sep. 19, 2024 (KR) 10-2024-0126761

(51) Int. Cl. G06F 3/041; G06F 3/044; G09G 3/32; H10H 29/49

(52) U.S. Cl. CPC G06F 3/0418; G06F 3/0412; G06F 3/04164; G06F 3/04166; G09G 3/32; H10H 29/49; G06F 3/044; G06F 2203/04102; G09G 2300/0426; G09G 2354/00

(57) ABSTRACT

A display device includes a driving circuit unit supplies a plurality of data signals to a plurality of pixel driving circuits and supplies a data compensation signal to a plurality of touch electrodes, and the data compensation signal and the plurality of data signals have opposite phases to each other.

### CROSS-REFERENCE TO RELATED APPLICATIONS

Pursuant to 35 U.S.C. § 119 (a), this application claims the benefit of an earlier filing date and right of priority to the Republic of Korea Patent Application No. 10-2024-0126761 filed on Sep. 19, 2024, which is hereby incorporated by reference in its entirety.

### TECHNICAL FIELD

The present disclosure relates to display apparatus.

### BACKGROUND

A display device is included in various electronic devices such as televisions (TVs), mobile phones, laptops, and tablets.

The display devices include an organic light emitting display (OLED) that emit light by themselves and a liquid crystal display (LCD) that require a separate light source.

Display devices including a light emitting diode (LED) have attracted attention as a next-generation display device. The light emitting diode is made of an inorganic material, not an organic material. Accordingly, compared to the liquid crystal display or the organic light emitting display, the display device including the light emitting diode has a faster lighting speed, excellent luminous efficiency, and displays an image having high luminance.

### SUMMARY

In accordance with an aspect of the present disclosure, a display device is provided. The display device comprising a display panel including a plurality of pixel driving circuits, a touch panel disposed on the display panel and including a plurality of touch electrodes, and a driving circuit unit electrically connected to the display panel and the touch panel, wherein the driving circuit unit supplies a plurality of data signals to the plurality of pixel driving circuits, wherein the driving circuit unit supplies a data compensation signal to the plurality of touch electrodes, and wherein the data compensation signal and the plurality of data signals have opposite phases to each other.

### BRIEF DESCRIPTION OF THE DRAWINGS

The accompanying drawings, which are included to provide a further understanding of the disclosure and are incorporated in and constitute a part of this application, illustrate implementations of the disclosure and together with the description serve to explain the principle of the disclosure.

FIG. 1 is an exploded perspective view of a display device according to an implementation of the present disclosure.

FIG. 2 is a plan view of a display device according to an implementation of the present disclosure.

FIG. 3 is an enlarged view of a display device according to an implementation of the present disclosure.

FIG. 4 is a diagram illustrating a circuit structure according to an implementation of the present disclosure.

FIG. 5 is a plan view of a display device according to an implementation of the present disclosure.

FIG. 6 is a plan view of a display device according to an implementation of the present disclosure.

FIG. 7 is a plan view of a display device according to an implementation of the present disclosure.

FIG. 8 is a cross-sectional view of a display device according to an implementation of the present disclosure.

FIG. 9 is a cross-sectional view of a display device according to an implementation of the present disclosure.

FIG. 10 is a diagram illustrating driving timing of a display panel and a touch panel according to an implementation of the present disclosure.

FIG. 11 is an enlarged view of a display device according to an implementation of the present disclosure.

FIG. 12 is a plan view of a display device according to an implementation of the present disclosure.

FIG. 13 is a plan view of a display device according to an implementation of the present disclosure.

FIG. 14 is a block diagram of a display device according to an implementation of the present disclosure.

FIG. 15 is a waveform diagram illustrating an example of a driving pulse according to FIG. 14.

FIG. 16 is a block diagram of a display device according to another implementation of the present disclosure.

FIG. 17 is a waveform diagram illustrating an example of a driving pulse according to FIG. 16.

FIGS. 18 to 21 are diagrams illustrating devices to which a display device according to implementations of the present disclosure is applied.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

The display device may include a display panel for displaying an image, and a touch panel in which a user may input information on the image. In some scenarios, due to an electrical coupling with the display panel, the touch panel may be affected by a driving signal of the display panel. In this case, noise occurs in the touch panel by the driving signal of the display panel, and touch sensitivity may be lowered.

Implementations of the present disclosure provide a display device that can reduce noise generation of a touch panel.

It is to be understood that both the foregoing general description and the following detailed description are exemplary and explanatory and are intended to provide further explanation of the subject matter as claimed.

Reference will now be made in detail to implementations of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and implementation methods thereof will be clarified through following implementations described with reference to the accompanying drawings. The present disclosure may, however, be embodied in different forms and should not be construed as limited to the implementations set forth herein. Rather, these implementations are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing implementations of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where ‘comprise’, ‘have’ and ‘include’ described in the present disclosure are used, another portion may be added unless ‘only˜’ is used. The terms of a singular form may include plural forms unless referred to the contrary.

In interpreting the components, it is interpreted as including the error range even if there is no separate explicit description of the error range.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used. The terms, such as “below,” “lower,” “above,” “upper” and the like, may be used herein to describe a relationship between element(s) as illustrated in the drawings. It will be understood that the terms are spatially relative and based on the orientation depicted in the drawings.

A description of a time relationship may include a case in which the temporal precedence relationship is described as “after”, “following”, or “before”, etc., and is not continuous unless “right away” or “directly”, is used.

Although the first, second, and the like are used to describe various components, these components are not limited by these terms. These terms are used only to distinguish one component from another. Therefore, a first component mentioned below may be a second component within a technical idea of a present disclosure.

It will be understood that, although the terms “first,” “second,” “A,” “B,” “(a),” and “(b)” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

If a component is stated to be “connected,” “coupled,” “linked,” or “attached” to another component, that component may be connected, coupled, linked, or attached directly to that other component, but it should be understood that other components may be interposed between each component that may be connected, coupled, linked, or attached indirectly, without any specific description.

It should be understood that if a component or layer is stated to be “in contact” or “overlapping” with another component or layer, the component or layer may be in direct contact or overlapping with another component or layer, but other components may be interposed between each component that may be indirectly in contact or overlapping without particular explicit description.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

“First direction”, “second direction”, “third direction”, “X-axis direction”, “Y-axis direction”, and “Z-axis direction” should not be interpreted only as a geometric relationship perpendicular to each other, but may mean that the configuration of the present disclosure has a wider direction within a range in which the configuration of the present disclosure may functionally act.

Features of each of the various implementations of the present specification may be partially or entirely coupled or combined with each other, technically various interworking and driving are possible, and each of the implementations may be independently implemented with respect to each other or may be implemented together in a related relationship.

Hereinafter, one implementation of the present disclosure will be described in detail with reference to the accompanying drawings.

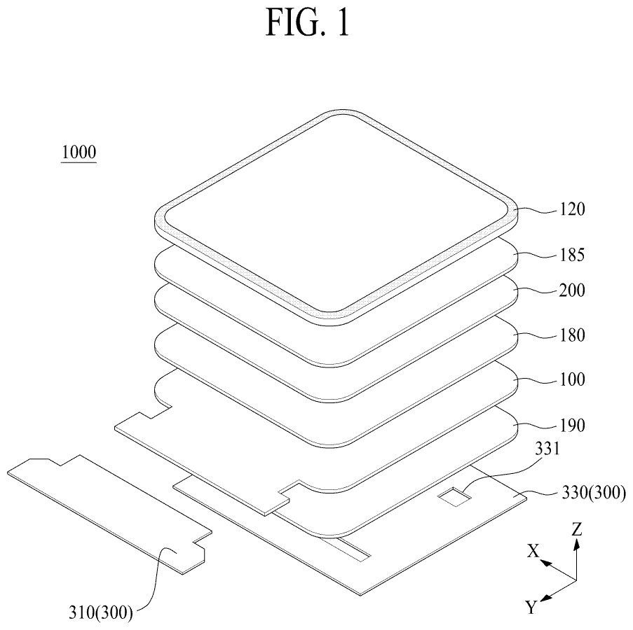

FIG. 1 is an exploded perspective view illustrating a display device according to an implementation of the present disclosure.

Referring to FIG. 1, a display device 1000 according to an implementation of the present disclosure may include a display panel 100, a cover member 120, a polarizing layer 180, an adhesive layer 185, a support substrate 190, and a driving circuit unit 300.

The display panel 100 may implement information, a video, and/or an image provided to a user. The display panel 100 may sense a user's touch.

The cover member 120 is disposed on the display panel 100 and may protect the display panel 100. The cover member 120 may be a member for protecting the display panel 100. The cover member 120 may be made of a transparent material. For example, the cover member 120 may be a cover window or a cover glass.

The display device 1000 may further include a polarizing layer 180 and an adhesive layer 185.

The polarizing layer 180 may be disposed on the display panel 100. The polarizing layer 180 may be disposed between the display panel 100 and the cover member 120. The polarizing layer 180 may prevent or reduce light generated from an external light source from entering the display panel 100 and affecting a light emitting device or the like.

The adhesive layer 185 may attach the cover member 120 to the display panel 100. The adhesive layer 185 may be disposed between the polarizing layer 180 and the cover member 120 to attach the cover member 120 to the polarizing layer 180. The adhesive layer 185 may include an optically clear adhesive (OCA), an optically clear resin (OCR), a pressure sensitive adhesive (PSA), or the like, but implementations of the present disclosure are not limited thereto.

The support substrate 190 may be disposed on a rear surface of the display panel 100. The support substrate 190 may reinforce rigidity of the display panel 100. For example, the support substrate 190 may be formed of a plastic material or a metal material, but implementations of the present disclosure are not limited thereto. The support substrate 190 may be a back plate, but implementations of the present disclosure are not limited thereto.

A portion of the display panel 100 may be bent to surround a side surface of the support substrate 190 and may be disposed on a rear surface of the support substrate 190.

The driving circuit unit 300 may be electrically connected to the display panel 100. The driving circuit unit 300 may generate a signal required to display an image on the display panel 100 and supply the signal to the display panel 100. The driving circuit unit 300 may include a flexible circuit board 310 and a printed circuit board 330. A combination of the flexible circuit board 310 and the printed circuit board 330 may be called as a circuit board.

The flexible circuit board 310 and the printed circuit board 330 may be disposed under the display panel 100. The flexible circuit board 310 and the printed circuit board 330 may be disposed on at least one edge of the display panel 100, but implementations of the present disclosure are not limited thereto. One side of the flexible circuit board 310 may be attached to the display panel 100, and the other side of the flexible circuit board 310 may be attached to the printed circuit board 330, but implementations of the present disclosure are not limited thereto. The flexible circuit board 310 may be a flexible film, but implementations of the present disclosure are not limited thereto.

The flexible circuit board 310 and the printed circuit board 330 may be disposed on a rear surface of the supporting substrate 190. The supporting substrate 190 may be disposed between the display panel 100 and the printed circuit board 330.

The printed circuit board 330 may include at least one hole 331, but implementations of the present disclosure are not limited thereto. An internal component that senses ambient light or temperature, which may be provided to a plurality of sensors, may be disposed in an area corresponding to the at least one hole 331. For example, the internal component may include an ambient light sensor (ALS) or a temperature sensor, but implementations of the present disclosure are not limited thereto. For example, the hole 331 may be a transmissive hole, etc., but implementations of the present disclosure are not limited thereto.

The display device 1000 according to an implementation of the present specification may further include a touch panel 200.

Touch panel 200 may sense a user's touch on display panel 100. For example, touch panel 200 may sense the user's touch through a touch pen or a finger.

The touch panel 200 according to an implementation of the present disclosure may be disposed between the display panel 100 and the cover member 120. For example, the touch panel 200 may be disposed between the cover member 120 and the polarizing layer 180. The touch panel 200 may be connected to or attached to the rear surface of the cover member 120 by a transparent adhesive member. The touch panel 200 may include a touch electrode layer having a touch electrode for sensing a user's finger touch or pen touch with respect to the display panel 100. The touch electrode layer may sense a change in capacitance of the touch electrode according to the user's touch. For example, the touch electrode layer may include an electrode structure corresponding to a mutual-capacitance type in which a plurality of touch driving electrodes and a plurality of touch sensing electrodes cross each other or a self-capacitance type in which only a plurality of touch sensing electrodes are formed.

The driving circuit unit 300 may be electrically connected to the touch panel 200. The driving circuit unit 300 may sense the change in capacitance of the touch electrode of the touch panel 200, may generate touch coordinate data corresponding to a user's touch position and may provide the data to the host control unit.

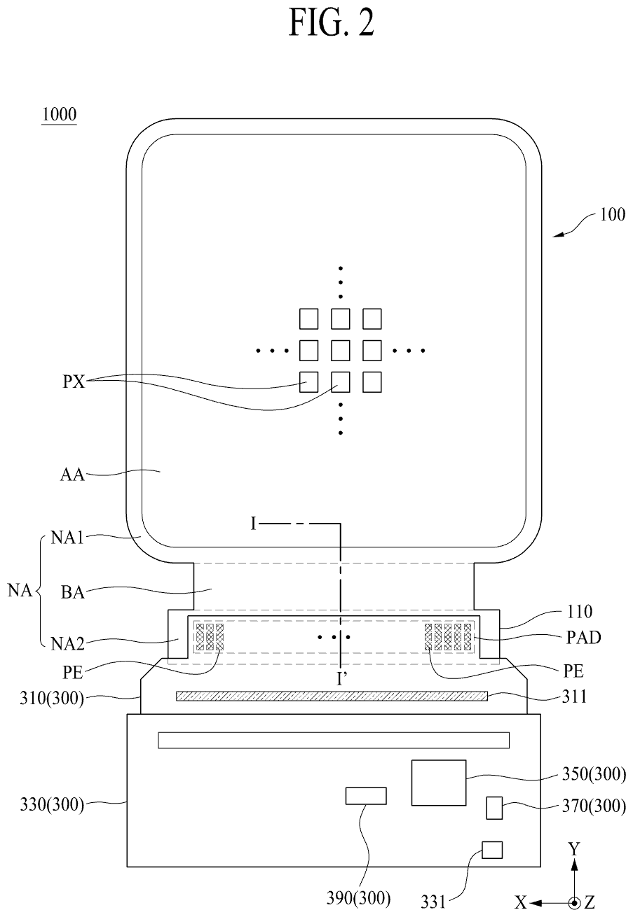

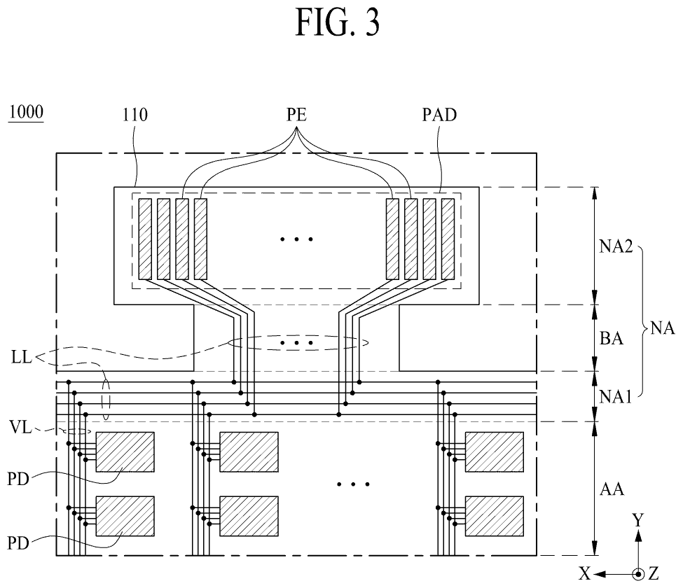

FIG. 2 is a plan view of a display device according to an implementation of the present disclosure. And, FIG. 3 is an enlarged view of a display device according to an implementation of the present disclosure.

Referring to FIGS. 2 and 3, the display device 1000 may include the display panel 100, the flexible circuit board 310, and the printed circuit board 330.

The display panel 100 may include a substrate 110. The substrate 110 may be a member that supports other components of the display device 1000. The substrate 110 may be made of an insulating material. For example, the substrate 110 may be made of glass or resin. The substrate 110 may be made of a material having flexibility. For example, the substrate 110 may be made of a plastic material having flexibility, such as polyimide (PI). However, implementations of the present disclosure are not limited thereto.

For example, the display panel 100 may include a display area AA and a non-display area NA. For example, the substrate 110 may include the display area AA and the non-display area NA. The display area AA and the non-display area NA are not limited to the substrate 110 but may be described throughout the display device 1000.

The display area AA may be an area in which an image is displayed. The display area AA may include a plurality of pixels PX. Each of the plurality of pixels PX may include a plurality of sub-pixels. A plurality of light emitting devices may be disposed in each of the plurality of sub-pixels. A plurality of light emitting devices may be configured to be different according to a type of the display device 1000. For example, when the display device 1000 is an inorganic light emitting display device, the light emitting device may be a light-emitting diode (LED), a micro light-emitting diode (Micro-LED), or a mini-light-emitting diode (MLED), but implementations of the present disclosure are not limited thereto.

The display area AA may be configured in various shapes according to the design of the display device 1000. For example, the display area AA may be configured in a rectangular shape having four rounded corners, but configurations of the present disclosure are not limited thereto. For another example, the display area AA may be configured in a rectangular shape having four right corners or circular shape, but configurations of the present disclosure are not limited thereto.

Referring to FIG. 3, a plurality of pixel driving circuits PD may be disposed in the display area AA. The plurality of pixel driving circuits PD may be circuits for driving light emitting devices of the plurality of sub-pixels. Each of the plurality of pixel driving circuits PD may include a plurality of transistors including driving transistors and storage capacitors. In addition, each of the plurality of pixel driving circuits PD may control a light emitting operation of the plurality of light emitting devices by supplying a control signal, a power source, and a driving current to the light emitting devices of the plurality of sub-pixels. For example, the pixel driving circuit PD may include a power line and a signal line for controlling light emission on/off and/or light emission time of the light emitting device. For example, each of the plurality of pixel driving circuits PD is a microchip or chipset, and may be a semiconductor packaging device with one fine size including a plurality of transistors and storage capacitors. For example, the plurality of pixel driving circuits PD may be driving drivers manufactured using a metal-oxide-silicon field effect transistor (MOSFET) manufacturing process on a semiconductor substrate, but implementations of the present disclosure are not limited thereto. The driving driver includes the plurality of pixel driving circuits PD and may drive the plurality of sub-pixels.

The non-display area NA may be a region surrounding the display area AA. The non-display area NA may be an area in which no image is displayed. Various wirings, driving circuit 331, and the like for driving the plurality of pixels PX of the display area AA may be disposed in the non-display area NA. For example, various wirings and driving circuit 331 may be mounted in the non-display area NA. A pad part PAD connected to an integrated circuit, a printed circuit, and the like may be disposed in the non-display area NA, but implementations of the present disclosure are not limited thereto.

According to an implementation of the present disclosure, the driving circuit 311 may include a driving integrated circuit. For example, the driving circuit 331 may be a data driving circuit and/or a gate driving circuit, but implementations of the present disclosure are not limited thereto. Wirings to which a control signal for controlling the driving circuits is supplied may be disposed in the non-display area NA. For example, the control signal may include various timing signals including a clock signal, an input data enable signal, and synchronization signals, but implementations of the present disclosure are not limited thereto. The control signal may be received through the pad part PAD. For example, link lines LL for transmitting a signal may be disposed in the non-display area NA. For example, the pad part PAD may be electrically connected to the driving circuit unit 300.

According to the present disclosure, the non-display area NA may include a first non-display area NA1, a bending area BA, and a second non-display area NA2. For example, the first non-display area NA may be an area surrounding at least a portion of the display area AA. The bending area BA may be an area extending from at least one of a plurality of sides of the first non-display area NA1 and may be a bendable area. The second non-display area NA2 is an area extending from the bending area BA, and the pad part PAD may be disposed. For example, the bending area BA may be bent, and a remaining area of the substrate 110 except for the bending area BA may be flat. In this case, as the bending area BA is bent, the second non-display area NA2 may be disposed on a rear surface of the display area AA. However, implementations of the present disclosure are not limited thereto.

A plurality of link lines LL may be disposed in the non-display area NA. The plurality of link lines LL may be wirings for transmitting various signals from one or more flexible circuit boards (or flexible films) 310 and the printed circuit board 330 to the display area AA. The plurality of link lines LL may extend from a plurality of pad electrodes PE of the second non-display area NA2 toward the bending area BA and the first non-display area NA1, and may be electrically connected to a plurality of driving lines VL of the display area AA. The plurality of pixel driving circuits PD may be driven by receiving signals from one or more flexible circuit boards (or flexible films) 310 and the printed circuit board 330 through the driving line VL in the display area AA and the link line LL in the non-display area NA.

For example, the plurality of driving lines VL may be wirings for transmitting a signal output from the flexible circuit board (or flexible film) 310 and the printed circuit board 330 to the plurality of pixel driving circuits PD with the plurality of link lines LL. The plurality of driving lines VL may be disposed in the display area AA and electrically connected to each of the plurality of pixel driving circuits PD. The plurality of driving lines VL may extend from the display area AA toward the non-display area NA and may be electrically connected to the plurality of link lines LL. Accordingly, the signal output from the flexible circuit board (or flexible film) 310 and the printed circuit board 330 may be transmitted to each of the plurality of pixel driving circuits PD through the plurality of link lines LL and the plurality of driving lines VL.

As the bending area BA is bent, portions of the plurality of link lines LL may be bent. Stress is concentrated on a portion of the bent link line LL, and thus, a crack may occur in the link line LL. Accordingly, the plurality of link lines LL may be formed of a conductive material having excellent ductility in order to reduce cracks when the bending area BA is bent. For example, the plurality of link lines LL may be formed of a conductive material having excellent ductility, such as gold (Au), silver (Ag), aluminum (Al), and the like, but implementations of the present disclosure are not limited thereto. The plurality of link lines LL may be formed of one of various conductive materials used in the display area AA. For example, the plurality of link lines LL may be formed of molybdenum (Mo), chromium (Cr), titanium (Ti), nickel (Ni), neodymium (Nd), copper (Cu), an alloy of silver (Ag) and magnesium (Mg), or the like, but implementations of the present disclosure are not limited thereto. The plurality of link lines LL may be a multilayer structure including various conductive materials. For example, the plurality of link lines LL may be a triple layer structure including titanium (Ti), aluminum (Al), and titanium (Ti), but implementations of the present disclosure are not limited thereto.

A plurality of link lines LL may be configured in various shapes to reduce stress. At least a portion of the plurality of link lines LL disposed on the bending area BA may extend in a same direction as the extending direction of the bending area BA, or may extend in a direction different from the extending direction of the bending area BA to reduce stress. For example, when the bending area BA extends in one direction from the first non-display area NA1 to the second non-display area NA2, at least a portion of the link line LL disposed on the bending area BA may extend in a direction inclined to the one direction. For another example, at least a portion of the plurality of link lines LL may include patterns of various shapes. For example, at least a portion of the plurality of link lines LL disposed on the bending area BA may have a shape in which a conductive pattern having at least one of a diamond shape, a rhombus shape, a trapezoidal shape, a triangular wave shape, a sawtooth wave shape, a sinusoidal shape, a circular shape, and an omega shape is repeatedly arranged, but implementations of the present disclosure are not limited thereto. Therefore, in order to minimize the stress concentrated on the plurality of link lines LL and the corresponding crack, the shape of the plurality of link lines LL may be formed in various shapes including the above-described shape, but implementations of the present disclosure are not limited thereto.

According to the present disclosure, a width of the second non-display area NA2 in which the plurality of pad electrodes PE are disposed may be wider than a width of the bending area BA in which only the plurality of link lines LL is disposed. A width of the display area AA in which the plurality of sub-pixels are disposed may be wider than the width of the bending area BA in which only the plurality of link lines LL are disposed. Although the width of the bending area BA is shown to be narrower than a width of other areas of the substrate 110, a shape of the substrate 110 including the bending area BA is exemplary, and implementations of the present disclosure are not limited thereto.

A pad part PAD including a plurality of pad electrodes PE may be disposed in the second non-display area NA2. A driving component including one or more the flexible circuit boards (or flexible films) 310 and the printed circuit board 330 may be attached to or bonded to the pad part PAD. The plurality of pad electrodes PE of the pad part PAD are electrically connected to one or more flexible circuit boards (or flexible films) 310, and various signals (or power) received from the printed circuit board 330 and the flexible circuit board (or flexible film) 310 may be transmitted to the plurality of pixel driving circuits PD of the display area AA.

The flexible circuit board (or flexible film) 310 may be a film in which various components are disposed on a base film having flexibility. For example, a driving IC 311 such as a gate driver IC or a data driver IC may be disposed on the flexible circuit board (or flexible film) 310, but implementations of the present disclosure are not limited thereto. The driving IC 311 may be a component that processes data and a driving signal for displaying an image. The driving IC 311 may be disposed by a method of chip on glass (COG) or chip on film (COF) or a tape carrier package (TCP) depending on a method of being mounted, but implementations of the present disclosure are not limited thereto. The flexible circuit board (or flexible film) 310 may be attached to or bonded on the plurality of pad electrodes PE through a conductive adhesive layer, but implementations of the present disclosure are not limited thereto.

The printed circuit board 330 may be a component electrically connected to one or more flexible circuit boards (or flexible films) 310, and supplying signals to the driving IC 311. The printed circuit board 330 may be disposed on one side of the flexible circuit board (or flexible film) 310, and may be electrically connected to the flexible circuit board (or flexible film). Circuit components such as a memory or various passive circuit elements may be additionally disposed on the printed circuit board 330 to supply various signals to the driving IC 311.

The driving circuit unit 300 according to an implementation of the present disclosure may further include a timing controller 350 and a power management integrated circuit (PMIC) 370.

The timing controller 350 may be mounted on the printed circuit board 330. The timing controller 350 may receive an image data and a timing synchronization signal provided from a host controller, convert the image data into a pixel data, and provide the pixel data to the driving IC 311. In addition, the timing controller 350 may control a driving timing of each of the driving IC 311 and the plurality of pixel driving circuits PD based on the timing synchronization signal.

The power management integrated circuit 370 may generate and output various power sources for driving of the display device 1000. For example, the power management integrated circuit 370 may generate and output a power supply voltage, a reference voltage, a cathode-on voltage, and a cathode-off voltage according to control of the timing controller 350 based on input power. For example, the driving voltage may be a voltage for driving a driving circuit or an integrated circuit. The reference voltage may be a voltage for controlling (or determining) brightness (or luminance) of light emitted from an image displayed in the display area AA or a light emitting device. The cathode-on voltage may be a voltage for turning on (or emitting) the light emitting device, and the cathode-off voltage may be a voltage for turning off the light emitting device. For example, the cathode-on voltage may be a first common voltage or a first low-potential power voltage, and the cathode-off voltage may be a second common voltage or a second low-potential power voltage, but implementations of the present disclosure are not limited thereto.

The driving circuit unit 300 according to an implementation of the present disclosure may further include a touch IC 390.

The touch IC 390 may be electrically connected to a touch electrode on the touch panel 200. The touch IC 390 may supply a touch driving signal to the touch electrode in response to a touch synchronization signal supplied from the timing controller 350, generate touch raw data corresponding to a change in capacitance of the touch electrode, and provide the generated touch raw data to the timing controller 350 or the host controller, but implementations of the present disclosure are not limited thereto. For example, the touch IC 390 may generate touch coordinate data based on the touch raw data and provide the generated touch coordinate data to the host controller. For example, the touch IC 390 may be integrated or embedded in the driving IC 311.

The timing controller 350 may control a voltage output from the power management integrated circuit 370 based on user touch information provided from the touch IC 390 or the host controller. For example, when the user adjusts the screen brightness (or luminance) of the display device 1000 through the touch panel 200 or a button, the timing controller 350 may generate a screen brightness signal corresponding to the user action (or setting) and provide reference voltage data and cathode-off voltage data (or second common voltage data) corresponding to the screen brightness signal to the power management integrated circuit 370. The power management integrated circuit 370 may generate and output a reference voltage and a cathode-off voltage based on each of the reference voltage data and the cathode-off voltage data provided from the timing controller 350.

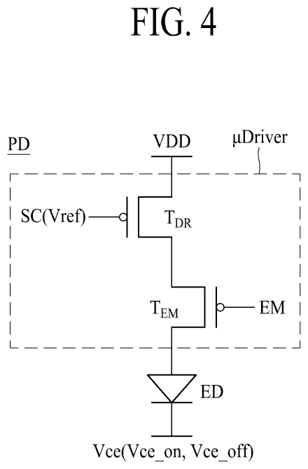

FIG. 4 is a diagram illustrating a circuit structure according to an implementation of the present disclosure. FIG. 4 is a diagram illustrating one micro-driver included in each of the plurality of pixel driving circuits illustrated in FIG. 3.

FIG. 4 illustrates that one light emitting device ED is connected to one micro-driver (μDriver), but is not limited thereto. For example, eight light emitting devices ED may be connected to one micro-driver (μDriver). For another example, 16 light emitting devices ED may be connected to one micro-driver (μDriver), 32 light emitting devices ED or 64 light emitting devices ED may be connected to one micro-driver (μDriver) at the same time. For example, the light emitting device ED may be a micro light emitting device, a micro light emitting diode, or a micro light emitting diode chip. For example, the light emitting device ED may have a scale of 1 μm to 100 μm, but configurations of the present disclosure are not limited thereto.

One micro-driver (μDriver) may include a driving transistor T_{DR} and a light emitting transistor T_{EM}, but implementations of the present disclosure are not limited thereto.

For example, a high potential power voltage VDD may be applied to a first electrode of the driving transistor T_{DR}, a first electrode of the light emitting transistor T_{EM} may be connected to a second electrode of the driving transistor T_{DR}, and a scan signal SC may be applied to a gate electrode of the driving transistor T_{DR}. The scan signal SC applied to the gate electrode of the driving transistor T_{DR} is a direct current power source, and a fixed reference voltage Vref may be applied to each frame, but implementations of the present disclosure are not limited thereto. For example, the reference voltage Vref may be changed every one or more frames. For example, the reference voltage Vref may be adjusted (or varied) according to screen brightness according to user action (or setting).

The second electrode of the driving transistor T_{DR} may be connected to a first electrode of the light emitting transistor T_{EM}, the light emitting device ED may be connected to a second electrode of the light emitting transistor T_{EM}, and a light emitting signal EM may be applied to a gate electrode of the light emitting transistor T_{EM}. The light emitting signal EM applied to the gate electrode of the light emitting transistor T_{EM} may be a pulse width modulation signal that changes every frame, but implementations of the present disclosure are not limited thereto. For example, the light emitting signal EM may include a duty-on period for turning on the light emitting transistor T_{EM} and a duty-off period for turning off the light emitting transistor T_{EM}. For example, the duty-on period of the light emitting signal EM may be set (or adjusted) by a gray scale corresponding to pixel data.

A first electrode of the light emitting device ED may be connected to the second electrode of the light emitting transistor T_{EM}, and a second electrode of the light emitting device ED may be connected to ground. For example, the first electrode of the light emitting device ED may be an anode electrode, and the second electrode of the light emitting device ED may be a cathode electrode, but implementations of the present disclosure are not limited thereto For example, the voltage applied from the light emitting transistor T_{EM} to the first electrode of the light emitting device ED may be an anode voltage. For example, the voltage applied to the low-potential power line may be a cathode voltage Vce. For example, the voltage applied to the low-potential power line may be a cathode-on voltage Vce-on or a cathode-off voltage Vce_off.

Each of the driving transistor T_{DR} and the light emitting transistor T_{EM} may be an n-type transistor or a p-type transistor.

The driving transistor T_{DR} may be turned on by the scan signal SC applied from a timing controller T-CON in the micro-driver (μDriver), and the light emitting transistor T_{EM} may be turned on by the light emitting signal EM. As a result, a driving current is applied to the light emitting device ED via the driving transistor T_{DR} and the light emitting transistor T_{EM} by the high potential power voltage VDD applied to the first electrode of the driving transistor T_{DR}, and thus the light emitting device ED may emit light. For example, the light emitting device ED may emit light while the cathode-on voltage Vce-on is applied to the low-potential power line and may not emit light while the cathode-off voltage Vce-off is applied to the low-potential power line.

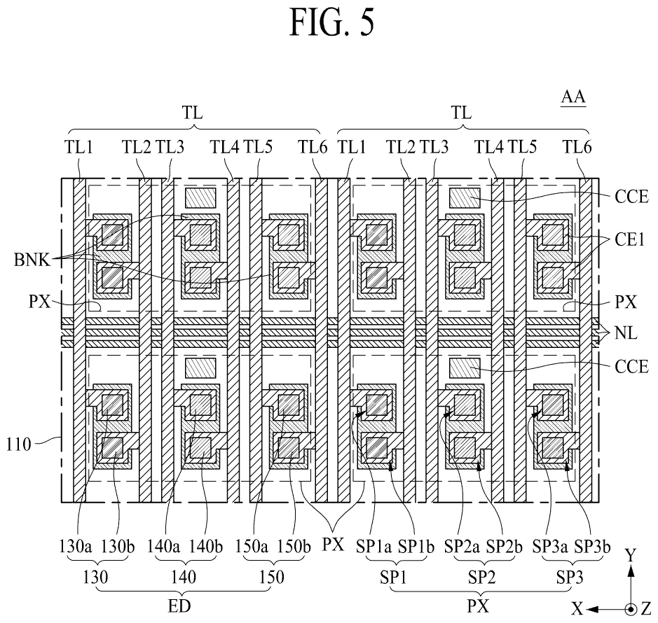

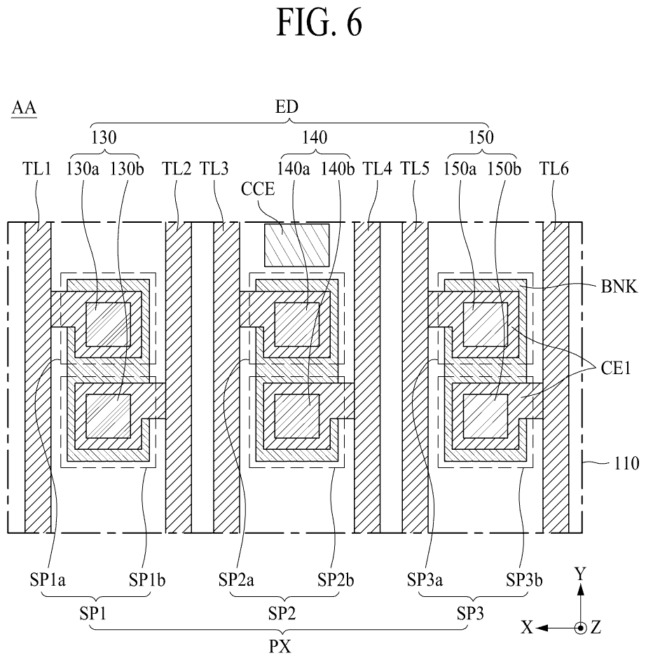

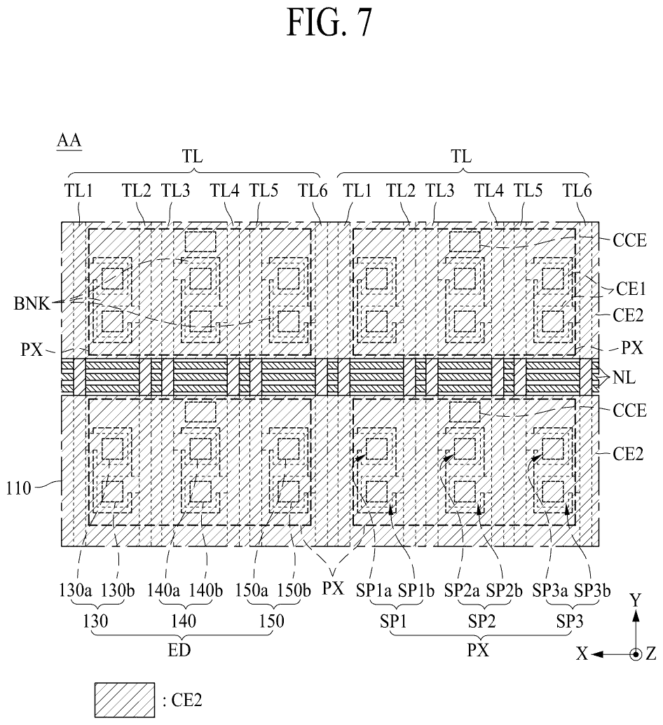

FIGS. 5 to 7 are plan views of a display device according to an implementation of the present disclosure. For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels.

Although FIGS. 5 and 7 illustrate a plurality of signal lines TL, a plurality of communication lines NL, a plurality of first electrodes CE1, a plurality of banks BNK, and a plurality of light emitting devices ED, implementations of the present disclosure are not limited thereto. FIG. 7 is an enlarged plan view in which the plurality of second electrodes CE2 are additionally disposed in FIG. 5, for convenience, an area overlapping the second electrodes CE2 is indicated by a dotted line.

Referring to FIGS. 5 to 7, a plurality of pixels PX including a plurality of sub-pixels may be disposed in the display area AA. Each of the plurality of sub-pixels includes a light emitting device ED and may independently emit light. The plurality of sub-pixels may be configured in a plurality of rows and a plurality of columns and may be disposed in a matrix form, but implementations of the present disclosure are not limited thereto.

The plurality of sub-pixels may include a first sub-pixel SP1, a second sub-pixel SP2, and a third sub-pixel SP3. For example, one of the first sub-pixel SP1, the second sub-pixel SP2, and the third sub-pixel SP3 may be a red sub-pixel, another may be a green sub-pixel, and the other may be a blue sub-pixel. Types of the plurality of sub-pixels are examples, and implementations of the present disclosure are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3.

The pair of first sub-pixels SP1 may include a first first sub-pixel SP1a (also referred to as a “1-1th sub-pixel SP1a”) and a first second sub-pixel SP1b (also referred to as a “1-2th sub-pixel SP1b”). The pair of second sub-pixels SP2 may include a second first sub-pixel SP2a (also referred to as a “2-1th sub-pixel SP2a”) and a second second sub-pixel SP2b (also referred to as a “2-2th sub-pixel SP2b”). The pair of third sub-pixels SP3 may include a third first sub-pixel SP3a (also referred to as a “3-1th sub-pixel SP3a”) and a third second sub-pixel SP3b (also referred to as a “3-2th sub-pixel SP3b”). For example, one pixel PX may include the 1-1th sub-pixel SP1a, the 1-2th sub-pixel SP2a, the 2-1th sub-pixel SP2a, the 2-2th sub-pixel SP2b, the 3-1th sub-pixel SP3a, and the 3-2th sub-pixel SP3b, but implementations of the present disclosure are not limited thereto.

The plurality of sub-pixels constituting one pixel PX may be variously arranged. For example, in one pixel PX, the pair of first sub-pixels SP1 may be disposed in the same column, the pair of second sub-pixels SP2 may be disposed in the same column, and the pair of third sub-pixels SP3 may be disposed in the same column. The first sub-pixel SP1, the second sub-pixel SP2, and the third sub-pixel SP3 may be disposed in the same row. The number and arrangement of a plurality of sub-pixels constituting one pixel PX are examples, and implementations of the present disclosure are not limited thereto.

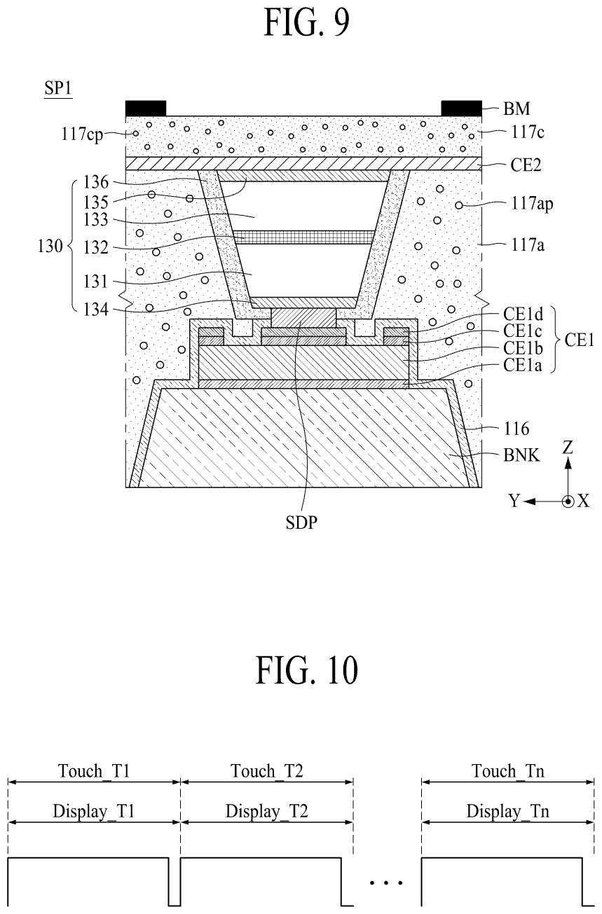

The plurality of signal lines TL may be disposed in an area between the plurality of sub-pixels. The plurality of signal lines TL may extend in a column direction between the plurality of sub-pixels. The plurality of signal lines TL may be lines that transmit the anode voltage from the pixel driving circuit PD (showed in FIG. 3) to the plurality of sub-pixels. For example, the plurality of signal lines TL may be electrically connected to the plurality of pixel driving circuits PD (showed in FIG. 3) and the first electrode CE1 of the plurality of sub-pixels. The anode voltage output from the pixel driving circuit PD (showed in FIG. 3) may be transmitted to the first electrode CE1 of the plurality of sub-pixels through the plurality of signal lines TL. For example, the first electrode CE1 may be an electrode electrically connected to the anode 134 of the light emitting device ED (showed in FIG. 9). Accordingly, the anode voltage from the signal line TL may be transmitted to the anode 134 of the light emitting device ED (showed in FIG. 9) through the first electrode CE1

Therefore, instead of forming a plurality of transistors and storage capacitors in each of the plurality of sub-pixels, a structure of the display device 1000 may be simplified by using a pixel driving circuit PD (showed in FIG. 3) in which the plurality of pixel circuits are integrated in one pixel driving circuit PD (showed in FIG. 3). In addition, since a circuit disposed in each of the plurality of sub-pixels is integrated in one pixel driving circuit PD (showed in FIG. 3), high efficiency and low power driving may be possible.

The plurality of signal lines TL may include a first signal line TL1, a second signal line TL2, a third signal line TL3, a fourth signal line TL4, a fifth signal line TL5, and a sixth signal line TL6. Each of the first signal line TL1 and the second signal line TL2 may be electrically connected to each of the pair of first sub-pixels SP1. Each of the third signal line TL3 and the fourth signal line TLA may be electrically connected to each of the pair of second sub-pixels SP2. Each of the fifth signal line TL5 and the sixth signal line TL6 may be electrically connected to each of the pair of third sub-pixels SP3.

The first signal line TL1 may be disposed at one side of the pair of first sub-pixels SP1, and the second signal line TL2 may be disposed at the other side of the pair of first sub-pixels SP1. The first signal line TL1 may be electrically connected to one of the pair of first sub-pixels SP1, for example, the first electrode CE1 of the 1-1th sub-pixel SP1a. The second signal line TL2 may be electrically connected to the remaining first sub-pixel SP1 of the pair of first sub-pixels SP1, for example, the first electrode CE1 of the 1-2th sub-pixel SP1b.

The third signal line TL3 may be disposed at one side of the pair of second sub-pixels SP2, and the fourth signal line TL4 may be disposed at the other side of the pair of second sub-pixels SP2. For example, the third signal line TL3 may be disposed adjacent to the second signal line TL2. The third signal line TL3 may be electrically connected to one of the pair of second sub-pixels SP2, for example, the first electrode CE1 of the 2-1th sub-pixel SP2a. The fourth signal line TLA may be electrically connected to the remaining second sub-pixel SP2 of the pair of second sub-pixels SP2, for example, the first electrode CE1 of the 2-2th sub-pixel SP2b.

The fifth signal line TL5 may be disposed at one side of the pair of third sub-pixels SP3, and the sixth signal line TL6 may be disposed at the other side of the pair of third sub-pixels SP3. For example, the fifth signal line TL5 may be disposed adjacent to the fourth signal line TLA. The sixth signal line TL6 may be disposed adjacent to the first signal line TL1 connected to the adjacent pixel PX. The fifth signal line TL5 may be electrically connected to one of the pair of third sub-pixels SP3, for example, the first electrode CE1 of the 3-1th sub-pixel SP3a. The sixth signal line TL6 may be electrically connected to the remaining third sub-pixel SP3 of the pair of third sub-pixels SP3, for example, the first electrode CE1 of the 3-2th sub-pixel SP3b.

The plurality of signal lines TL may be formed of a conductive material. For example, the plurality of signal lines TL may be formed of the conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but implementations of the present disclosure are not limited thereto. For another example, the plurality of signal lines TL may be formed of a multilayer structure of a conductive material. For example, the plurality of signal lines TL may be formed of the multilayer structure in which titanium (Ti), aluminum (Al), titanium (Ti), and indium tin oxide (ITO) are stacked, but implementations of the present disclosure are not limited thereto.

The plurality of communication lines NL may be disposed in an area between the plurality of pixels PX. The plurality of communication lines NL may be disposed to extend in a row direction in an area between the plurality of pixels PX. The plurality of communication lines NL may be disposed in an area between the plurality of second electrodes CE2, and may not overlap the plurality of second electrodes CE2. For example, the plurality of communication lines NL may be wirings used for short-range communication such as near field communication (NFC). The plurality of communication lines NL may function as antennas. For example, the plurality of communication lines NL may be a plurality of connection lines, etc., but implementations of the present disclosure are not limited thereto.

According to the present disclosure, banks BNK may be disposed in each of the plurality of sub-pixels. The plurality of banks BNK may be structures in which the plurality of light emitting devices ED are disposed. The plurality of banks BNK may guide positions of the plurality of light emitting devices ED in a transfer process of the plurality of light emitting devices ED. The plurality of light emitting devices ED may be transferred onto the plurality of banks BNK in the transfer process of the plurality of light emitting devices ED. The plurality of banks BNK may be bank patterns or construction, but implementations of the present disclosure are not limited thereto.

The bank BNK of the first sub-pixel SP1, the bank BNK of the second sub-pixel SP2, and the bank BNK of the third sub-pixel SP3 may be disposed to be spaced apart from each other. The bank BNK of the first sub-pixel SP1, the bank BNK of the second sub-pixel SP2, and the bank BNK of the third sub-pixel SP3 may be configured to be separated. Accordingly, the bank BNK of the first sub-pixel SP1, the second sub-pixel SP2, and the third sub-pixel SP3 to which different types of light emitting devices ED are transferred may be easily identified.

The bank BNK of the 1-1th sub-pixel SP1a and the bank BNK of the 1-2th sub-pixel SP1b may be connected to each other or may be spaced apart from each other. For example, the bank BNK of the 1-1st sub-pixel SP1a and the bank BNK of the 1-2th sub-pixel SP1b in which the same light emitting device ED is disposed may be connected, separated, or spaced apart from each other in consideration of design such as transfer process requirements. The bank BNK of the 2-1th sub-pixel SP2a and the bank BNK of the 2-2th sub-pixel SP2b may be connected to each other or may be spaced apart from each other. The bank BNK of the 3-1th sub-pixel SP3a and the bank BNK of the 3-2th sub-pixel SP3b may be connected to each other or may be spaced apart from each other. Accordingly, the bank BNK of the pair of first sub-pixels SP1, the bank BNK of the pair of second sub-pixels SP2, and the bank BNK of the pair of third sub-pixels SP3 may be variously formed, and implementations of the present disclosure are not limited thereto.

For example, the plurality of banks BNK may be formed of an organic insulating material. The plurality of banks BNK may be formed of a single layer or a multilayer of an organic insulating material. For example, the plurality of banks BNK may be formed of a photo resist, a polyimide (PI), an acryl-based material, or the like, but implementations of the present disclosure are not limited thereto.

The first electrode CE1 may be disposed in each of the plurality of sub-pixels. The first electrode CE1 may be disposed on the bank BNK while overlapping the bank BNK. The first electrode CE1 may be electrically connected to one of the plurality of signal lines TL. At least a portion of the first electrode CE1 may extend to an outside of the bank BNK to be electrically connected to the signal line TL closest to the first electrode CE1. A portion of the first electrode CE1 may overlap the bank BNK, and the remaining area of the first electrode CE1 may not overlap the bank BNK.

For example, a portion of the first electrode CE1 of the 1-1th sub-pixel SP1a may extend to one side area of the 1-1th sub-pixel SP1a to be electrically connected to the first signal line TL1, and a portion of the first electrode CE1 of the 1-2th sub-pixel SP1b may extend to the other side area of the 1-2th sub-pixel SP1b to be electrically connected to the second signal line TL2. A portion of the first electrode CE1 of the 2-1th sub-pixel SP2a may extend to one side area of the 2-1th sub-pixel SP2a to be electrically connected to the third signal line TL3, and a portion of the first electrode CE1 of the 2-2th sub-pixel SP2b may extend to the other side area of the 2-2th sub-pixel SP2b to be electrically connected to the fourth signal line TL4. A portion of the first electrode CE1 of the 3-1th sub-pixel SP3a may extend to one side area of the 3-1th sub-pixel SP3a to be electrically connected to the fifth signal line TL5, and a portion of the first electrode CE1 of the 3-2th sub-pixel SP3b may extend to the other side area of the 3-2th sub-pixel SP3b to be electrically connected to the sixth signal line TL6.

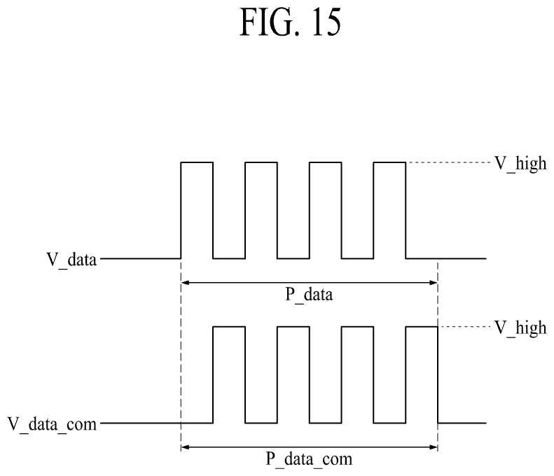

The first electrode CE1 is electrically connected to the anode electrode 134 (showed in FIG. 14) of the light emitting device ED. The anode voltage from the pixel driving circuit PD (showed in FIG. 3) may be transmitted to the light emitting device ED via the signal line TL and the first electrode CE1. A different voltage may be applied to the first electrode CEL of each of the plurality of sub-pixels according to an image that is displayed. For example, different voltages may be applied to the first electrode CE1 of each of the plurality of sub-pixels. Accordingly, the first electrode CE1 may be a pixel electrode, and implementations of the present disclosure are not limited thereto.

The first electrode CE1 may be formed of a conductive material. For example, the first electrode CE1 may be formed integrally with the plurality of signal lines TLs. For example, the first electrode CE1 may be formed of the same conductive material as the plurality of signal lines TLs, but implementations of the present disclosure are not limited thereto. For example, the first electrode CE1 may be formed of the conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), and the like, but implementations of the present disclosure are not limited thereto. For another example, the first electrode CE1 may be formed of a multilayer structure of the conductive material. For example, the plurality of first electrodes CE1 may be formed of the multilayer structure in which titanium (Ti), aluminum (Al), titanium (Ti), and indium tin oxide (ITO) are stacked, but implementations of the present disclosure are not limited thereto.

The plurality of light emitting devices ED may be disposed on the first electrode CE1 to overlap the bank BNK and the first electrode CE1. The entire area of the plurality of light emitting devices ED may overlap the bank BNK and the first electrode CE1. The plurality of light emitting devices ED may be in contact with the first electrode CE1 so as to overlap the bank BNK and the first electrode CE1.

The plurality of light emitting devices ED are disposed on the first electrode CE1 and may be electrically connected to the first electrode CE1. Accordingly, the light emitting device ED may emit light by receiving the anode voltage from the pixel driving circuit PD through the signal line TL and the first electrode CE1.

The plurality of light emitting devices ED may include a first light emitting device 130, a second light emitting device 140, and a third light emitting device 150.

The first light emitting device 130 may be disposed in the first sub-pixel SP1. The second light emitting device 140 may be disposed in the second sub-pixel SP2. The third light emitting device 150 may be disposed in the third sub-pixel SP3. For example, one of the first light emitting device 130, the second light emitting device 140, and the third light emitting device 150 may be a red light emitting device, another may be a green light emitting device, and the other may be a blue light emitting device, but implementations of the present disclosure are not limited thereto. Accordingly, light of various colors including white may be implemented by combining red light, green light, and blue light emitted from the plurality of light emitting devices ED. Types of the plurality of light emitting devices ED are examples, and implementations of the present disclosure are not limited thereto.

The first light emitting device 130 may include a first first light emitting device 130a (also referred to as a “1-1th light emitting device 130a”) disposed in the 1-1th sub-pixel SP1a and a first second light emitting device 130b (also referred to as a “1-2th light emitting device 130b”) disposed in the 1-2th sub-pixel SP1b. The second light emitting device 140 may include a second first light emitting device 140a (also referred to as a “2-1th light emitting device 140a”) disposed in the 2-1th sub-pixel SP2a and a second second light emitting device 140b (also referred to as a “2-2th light emitting device 140b”) disposed in the 2-2th sub-pixel SP2b. The third light emitting device 150 may include a third first light emitting device 150a (also referred to as a “3-1th light emitting device 150a”) disposed in the 3-1th sub-pixel SP3a and a third second light emitting device 150b (also referred to as a “3-2th light emitting device 150b”) disposed in the 3-2th sub-pixel SP3b.

The second electrode CE2 may be disposed in each of the plurality of sub-pixels. The second electrode CE2 may be disposed on the light emitting device ED. The second electrode CE2 may be electrically connected to the pixel driving circuit PD (showed in FIG. 3) through a plurality of contact electrodes CCE. For example, the second electrode CE2 may be electrically connected to the cathode electrode 135 (showed in FIG. 9) of the light emitting device ED to transmit the cathode voltage from the pixel driving circuit PD (showed in FIG. 3) to the light emitting device ED.

The same cathode voltage may be applied to the second electrode CE2 of each of the plurality of sub-pixels. For example, the same voltage may be applied to the second electrode CE2 of each of the plurality of sub-pixels and the cathode electrode 135 (showed in FIG. 9) of the light emitting device ED. Accordingly, the second electrode CE2 may be a common electrode, but implementations of the present disclosure are not limited thereto.

According to another implementation of the present disclosure, the cathode voltage applied to the second electrode CE2 of each of the plurality of sub-pixels may be changed according to the reference voltage Vref (showed in FIG. 4). For example, the cathode voltage may be adjusted (or varied) according to screen brightness according to user action (or setting).

The second electrode CE2 according to an implementation of the present disclosure may have a size corresponding to one row (or horizontal line). For example, the second electrode CE2 may have a width corresponding to one row (or horizontal line) and may extend along a column direction (or a first direction X). For example, the second electrode CE2 may be commonly connected to the light emitting devices ED in each of the pixels PX arranged along the column direction (or the first direction X). For example, the second electrode CE2 may be commonly connected to the cathode (or cathode terminal) 135 (showed in FIG. 9) of the light emitting devices ED in each of the 16 pixels PX arranged along the column direction (or the first direction X), but implementations of the present disclosure are not limited thereto. For example, the second electrode CE2 may be commonly connected to the cathode (or cathode terminal) 135 (showed in FIG. 9) of the 96 light emitting devices ED arranged along the column direction (or the first direction X). For example, the second electrode CE2 may be commonly connected to the cathode (or cathode terminal) 135 (showed in FIG. 9) of 192 light emitting devices ED in one row (or horizontal line), but implementations of the present specification are not limited thereto.

For example, some of the second electrodes CE2 of each of the plurality of sub-pixels may be spaced apart from each other or to be separated from each other. For example, the second electrode CE2 connected to the pixels PX of the n-th row and the second electrode CE2 connected to the pixels PX of the n+1th row may be spaced apart from each other. For example, the plurality of second electrodes CE2 may be spaced apart from each other with the plurality of communication lines NL extending in a row direction interposed therebetween. Accordingly, the number of the plurality of sub-pixels may be greater than the number of the plurality of second electrodes CE2.

The plurality of second electrodes CE2 may be formed of a transparent conductive material, but implementations of the present disclosure are not limited thereto. The plurality of second electrodes CE2 may be formed of the transparent conductive material so that light emitted from the light emitting device ED is directed to an upper portion of the second electrode CE2. For example, the second electrode CE2 may be formed of the transparent conductive material such as indium tin oxide (ITO), indium zinc oxide (IZO), indium gallium zinc oxide (IGZO), or the like, but implementations of the present disclosure are not limited thereto.

A plurality of contact electrodes CCE may be disposed on the substrate 110. For example, the plurality of contact electrodes CCE may be spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

The plurality of contact electrodes CCE may be electrically connected to the plurality of second electrodes CE2. The plurality of contact electrodes CCE may be disposed between the substrate 110 and the plurality of second electrodes CE2 to transmit the cathode voltage from the pixel driving circuit PD (showed in FIG. 3) to the second electrode CE2.

For example, when a micro LED is used as the light emitting device ED, a plurality of micro LEDs may be formed in a wafer and the micro LEDs may be transferred to the substrate 110 to manufacture the display panel 100. Various defects may occur in the process of transferring the plurality of light emitting devices ED having a micro size from the wafer to the substrate 110. For example, a non-transmission defect in which the light emitting device ED is not transferred may occur in some sub-pixels, and a defect in which the light emitting device ED is transferred out of a correct position due to an alignment error may occur in some sub-pixels. The transfer process has proceeded normally, but the transferred light emitting device ED itself may be a defect. Accordingly, the plurality of the same light emitting devices ED may be transferred to one sub-pixel in consideration of the defect during the transfer process of the plurality of light emitting devices ED. After the lighting test of the plurality of light emitting devices ED is performed, only one light emitting device ED finally determined to be normal may be used.

For example, the 1-1th light emitting device 130a and the 1-2th light emitting device 130b may be transferred to one pixel PX, and it is possible to inspect whether there is a defect in the 1-1th light emitting device 130a and the 1-2th light emitting device 130b. If both of the 1-1th light emitting device 130a and the 1-2th light emitting device 130b are determined to be normal, only the 1-1th light emitting device 130b may be used and the 1-2th light emitting device 130b may be not used. As another example, if only the 1-2th light emitting device 130b of the 1-1th light emitting device 130a and the 1-2th light emitting device 130b is determined to be normal, the 1-1th light emitting device 130a may not be used and only the 1-2th light emitting device 130b may be used. Therefore, even if the plurality of the same light emitting devices ED are transferred to one pixel PX, only one light emitting device ED may be finally used.

Accordingly, one of the pair of light emitting devices ED may be a main or primary light emitting device ED, and the other light emitting device ED may be a redundancy light emitting device ED. The redundancy light emitting device ED may be an extra light emitting device ED transferred to prepare for a defect in the main light emitting device ED. When the main light emitting device ED is defective, the redundancy light emitting device ED may be used instead of the main light emitting device ED. Accordingly, the main light emitting device ED and the redundancy light emitting device ED are transferred to one pixel PX, thereby minimizing deterioration of display quality due to defects in the main light emitting device ED and the redundancy light emitting device ED. For example, the 1-1th light emitting device 130a, the 2-1th light emitting device 140a, and the 3-1th light emitting device 150a transferred to one pixel PX may be used as the main light emitting device ED, and the 1-2th light emitting device 130b, the 2-2th light emitting device 140b, and the 3-2th light emitting device 150b may be used as the redundancy light emitting device ED.

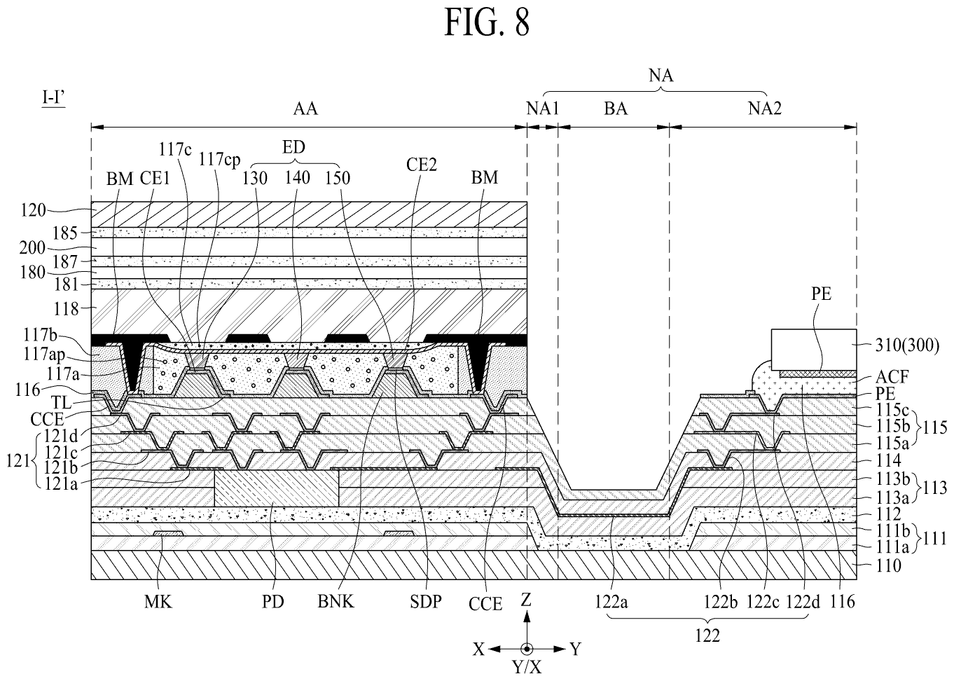

FIG. 8 is a cross-sectional view of a display device according to an implementation of the present disclosure. And, FIG. 9 is a cross-sectional view of a display device according to an implementation of the present disclosure. For example, FIG. 8 is a cross-sectional view of the display area AA, the first non-display area NA, the bending area BA, and the second non-display area NA2, and FIG. 9 is a cross-sectional view of a portion of the display area AA.

Referring to FIG. 8, a first buffer layer 111a and a second buffer layer 111b may be disposed in the remaining area of the substrate 110 except the bending area BA. A combination of the first buffer layer 111a and the second buffer layer 111b might be called as a buffer layer 111.

The first buffer layer 111a and the second buffer layer 111b may be disposed in the display area AA, the first non-display area NA1, and the second non-display area NA2. The first buffer layer 111a and the second buffer layer 111b may reduce penetration of moisture or impurities through the substrate 110. The first buffer layer 111a and the second buffer layer 111b may be formed of an inorganic insulating material. For example, the first buffer layer 111a and the second buffer layer 111b may be formed of a single layer or a multilayer composed of silicon oxide (SiOₓ) or silicon nitride (SiNₓ), but implementations of the present disclosure are not limited thereto

For example, portions of the first buffer layer 111a and the second buffer layer 111b on the bending area BA may be removed. An upper surface of the substrate 110 disposed in the bending area BA may be exposed by the first buffer layer 111a and the second buffer layer 111b. The first buffer layer 111a and the second buffer layer 111b made of the inorganic insulating material may be removed from the bending area BA, thereby minimizing cracks in the first buffer layer 111a and the second buffer layer 111b that may occur during bending.

A plurality of alignment keys MK may be disposed between the first buffer layer 111a and the second buffer layer 111b. The plurality of alignment keys MK may be identify a position of the pixel driving circuit PD during a manufacturing process of the display panel 100. For example, the plurality of alignment keys MK may align the position of the pixel driving circuit PD transferred onto an adhesive layer 112. For another example, the plurality of alignment keys MK may be omitted.

An adhesive layer 112 may be disposed on the second buffer layer 111b. The adhesive layer 112 may be disposed in the display area AA, the first non-display area NA1, the bending area BA, and the second non-display area NA2. For another example, a portion of the adhesive layer 112 may be removed from the non-display area NA including the bending area BA. For example, the adhesive layer 112 may be formed of one of an adhesive polymer, an epoxy resin, a UV curable resin, a polyimide-based resin, an acrylate-based material, a urethane-based material, and a polydimethylsiloxane (PDMS), but implementations of the present disclosure are not limited thereto.

In the display area AA, the pixel driving circuit PD may be disposed on the adhesive layer 112. When the pixel driving circuit PD is implemented as a driving driver, the driving driver may be mounted on the adhesive layer 112 through a transfer process, but implementations of the present disclosure are not limited thereto.

A first protective layer 113a and a second protective layer 113b may be disposed on the adhesive layer 112 and the pixel driving circuit PD. A combination of the first protective layer 113a and the second protective layer 113b might be called as a protective layer 113. The first protective layer 113a and the second protective layer 113b may surround a side surface of the pixel driving circuit PD, but implementations of the present disclosure are not limited thereto. For example, the second protective layer 113b may cover at least a portion of an upper surface of the pixel driving circuit PD. For example, at least one of the first protective layer 113a and the second protective layer 113b disposed on the bending area BA may be omitted. For example, the first protective layer 113a is entirely disposed in the display area AA and the non-display area NA, and the second protective layer 113b is partially disposed in the display area AA, the first non-display area NA1, and the second non-display area NA2 and may not be disposed in the bending area BA. For example, a portion of the second protective layer 113b in the bending area BA may be removed. However, implementations of the present disclosure are not limited thereto.

The first protective layer 113a and the second protective layer 113b may be formed of an organic insulating material, but implementations of the present disclosure are not limited thereto. For example, the first protective layer 113a and the second protective layer 113b may be formed of a photo resist, polyimide (PI), a photoacryl-based material, or the like, but implementations of the present disclosure are not limited thereto. For example, the first protective layer 113a and the second protective layer 113b may be an overcoating layer or an insulating layer, but implementations of the present disclosure are not limited thereto.

According to an implementation of the present disclosure, a wiring layer (or a pixel wiring layer) may be disposed on the protective layer 113b. For example, the wiring layer may surround or cover the pixel driving circuit PD. The wiring layer may include a plurality of first connection lines 121.

The plurality of first connection lines 121 may be disposed on the second protective layer 113b. For example, the plurality of first connection lines 121 may be disposed on the second protective layer 113b in the display area AA. The plurality of first connection lines 121 may be wirings (or intermediate wirings or jumping wirings) electrically connecting the pixel driving circuit PD to other components and/or wirings in different layers. For example, the pixel driving circuit PD may be electrically connected to the plurality of signal lines TL, the plurality of contact electrodes CCE, and the like through the plurality of first connection lines 121.

The plurality of first connection lines 121 may include a plurality of first first connection lines 121a (also referred to as “1-1th connection lines 121a”, a plurality of first second connection lines 121b (also referred to as “1-2th connection lines 121b”), a plurality of first third connection lines 121c (also referred to as “1-3th connection lines 121c”), and a plurality of first fourth connection lines 121d (also referred to as “1-4th connection lines 121d”), but implementations of the present disclosure are not limited thereto. For example, the plurality of 1-1th connection lines 121a may be disposed on the second protective layer 113b. The plurality of 1-1th connection lines 121a may be electrically connected to the pixel driving circuit PD. The plurality of 1-1th connection lines 121a may transmit voltages output from the pixel driving circuit PD to the first electrode CE1 or the second electrode CE2.

A third protective layer 114 may be disposed on the second protective layer 113b. The third protective layer 114 may be disposed on the entire display area AA and the non-display area NA. In the bending area BA, the third protective layer 114 may disposed on or cover a side surface of the second protective layer 113b and an upper surface of the first protective layer 113a. The third protective layer 114 may be formed of an organic insulating material. For example, the third protective layer 114 may be formed of a photo resist, polyimide (PI), a photoacryl-based material, or the like, but implementations of the present disclosure are not limited thereto. For example, the first protective layer 113a, the second protective layer 113b, and the third protective layer 114 may be formed of the same material, but implementations of the present disclosure are not limited thereto.

The plurality of 1-2th connection lines 121b may be disposed on the third protective layer 114. The plurality of 1-2th connection lines 121b may be connected to the pixel driving circuit PD through the 1-1th connection lines 121a or may be directly connected to the pixel driving circuit PD. For example, a portion of the 1-2th connection line 121b may be directly connected to the pixel driving circuit PD through a contact hole of the third protective layer 114. The other portion of the 1-2th connection wiring 121b may be electrically connected to the 1-1th connection line 121a through a contact hole of the third protective layer 114. However, implementations of the present disclosure are not limited thereto. For example, the voltage output from the pixel driving circuit PD may be transmitted to the first electrode CEL or the second electrode CE2 through connection lines different from the plurality of 1-2th connection lines 121b.

The display device 1000 according to an implementation of the present disclosure may further include an insulating layer 115 on a wiring layer. The insulating layer 115 may electrically insulate the plurality of first connection lines 121 and cover the plurality of first connection lines 121. For example, the insulating layer 115 may include first to third insulating layers 115a, 115b and 115c.

A first insulating layer 115a may be disposed on the plurality of 1-2th connection lines 121b. The first insulating layer 115a may be disposed in the entire display area AA and the non-display area NA, but implementations of the present disclosure are not limited thereto. The first insulating layer 115a may be formed of an organic insulating material, but implementations of the present disclosure are not limited thereto. For example, the first insulating layer 115a may be formed of a photo resist, polyimide (PI), a photoacryl-based material, or the like, but implementations of the present disclosure are not limited thereto.

The plurality of 1-3th connection lines 121c may be disposed on the first insulating layer 115a. The plurality of 1-3th connection lines 121c may be electrically connected to the plurality of 1-2th connection lines 121b. For example, the 1-3th connection lines 121c may be electrically connected to the 1-2th connection lines 121b through a contact hole of the first insulating layer 115a.

A second insulating layer 115b may be disposed on the plurality of 1-3th connection lines 121c. The second insulating layer 115b may be disposed in the remaining area except for the bending area BA, but implementations of the present disclosure are not limited thereto. The second insulating layer 115b may be disposed in the display area AA, the first non-display area NA1, and the second non-display area NA2, but implementations of the present disclosure are not limited thereto. For example, at least a portion of the second insulating layer 115b disposed in the bending area BA may be removed. The second insulating layer 115b may be formed of an organic insulating material, but implementations of the present disclosure are not limited thereto. For example, the second insulating layer 115b may be formed of a photo resist, polyimide (PI), a photoacryl-based material, or the like, but implementations of the present disclosure are not limited thereto.

The plurality of 1-4th connection lines 121d may be disposed on the second insulating layer 115b. The plurality of 1-4th connection lines 121d may be electrically connected to the plurality of 1-3th connection lines 121c. For example, the 1-4th connection lines 121d may be electrically connected to the 1-3th connection lines 121c through a contact hole of the second insulating layer 115b.

The 1-4th connection line 121d may be connected to the contact electrode CCE through a contact hole of the third insulating layer 115c. Accordingly, the contact electrode CCE and the pixel driving circuit PD may be electrically connected to each other by the first connection line 121.

The 1-4th connection line 121d may be directly connected to the signal line TL through a contact hole disposed in the third insulating layer 115c, or may be electrically connected to the signal line TL through other additional lines or electrodes. Accordingly, the signal line TL and the pixel driving circuit PD may be electrically connected by the first connection line 121.

A plurality of second connection lines 122 may be disposed on the second protective layer 113b. For example, the plurality of second connection lines 122 may be disposed on the second protective layer 113b in the non-display area NA. The plurality of second connection lines 122 may be wirings for transmitting a signal received from the flexible circuit board (or a flexible film) 310 (showed in FIG. 2) and a printed circuit board 330 (showed in FIG. 2) to the pixel driving circuit PD of the display area AA.

For example, the plurality of second connection lines 122 may be electrically connected to the plurality of pad electrodes PE to receive signals from flexible circuit boards (or flexible films) 310 (showed in FIG. 2) and printed circuit boards 330 (showed in FIG. 2).

For example, the plurality of second connection lines 122 may extend from the pad part PAD (showed in FIG. 2) toward the display area AA to transmit signals to the wirings of the display area AA. In this case, the plurality of second connection lines 122 may function as link lines LL (showed in FIG. 3).

The plurality of second connection lines 122 may include a 2-1th connection line 122a, a 2-2th connection line 122b, a 2-3th connection line 122c, and a 2-4th connection line 122d.

The plurality of 2-1th connection lines 122a may be disposed on the second protective layer 113b. The plurality of 2-1th connection lines 122a may extend from the second non-display area NA2 to the bending area BA and the first non-display area NA1. The plurality of 2-1 connection lines 122a may transmit signals received from the flexible circuit board (or flexible film 310 (showed in FIG. 2) and the printed circuit board 330 (showed in FIG. 2) to the pixel driving circuit PD of the display area AA.

According to an implementation of the present disclosure, the plurality of 2-1 connection lines 122a may be electrically connected to the pad electrode PE and the pixel driving circuit PD, respectively. For example, the 2-1 connection line 122a may extend to the display area AA to be directly connected to the pixel driving circuit PD in the display area AA, or may be electrically connected to the pixel driving circuit PD through other additional wirings or electrodes. In addition, the 2-1 connection line 122a may be electrically connected to the pad electrode PE in the second non-display area NA2 via the 2-2 connection line 122b, the 2-3 connection line 122c, and the 2-4 connection wiring 122d. Therefore, the pixel driving circuit PD and the pad electrode PE may be electrically connected by the second connection line 122.

The plurality of 2-2th connection lines 122b may be disposed on the third protective layer 114. The plurality of 2-2th connection lines 122b may be disposed in the second non-display area NA2. The 2-2 connection lines 122b may be electrically connected to the 2-1th connection lines 122a through a contact hole of the third protective layer 114. Therefore, signals from the flexible circuit board (or flexible film) 310 (showed in FIG. 2) and the printed circuit board 330 (showed in FIG. 2) may be transmitted to the 2-1 connection lines 122a through the 2-2 connection lines 122b.

The 2-3th connection line 122c may be disposed on the first insulating layer 115a. The 2-3th connection line 122c may be disposed in the second non-display area NA2. The 2-3th connection line 122c may be electrically connected to the 2-2th connection line 122b through a contact hole of the first insulating layer 115a. Accordingly, signals from the flexible circuit board (or flexible film) 310 (showed in FIG. 2) and the printed circuit board 330 (showed in FIG. 2) may be transmitted to the 2-1th connection line 122a through the 2-3th connection line 122c and the 2-2th connection line 122b.

The 2-4th connection line 122d may be disposed on the second insulating layer 115b. The 2-4th connection line 122d may be disposed in the second non-display area NA2. The 2-4th connection line 122d may be electrically connected to the 2-3th connection line 122c through a contact hole of the second insulating layer 115b. The 2-4th connection line 122d may be electrically connected to the pad electrode PE through a contact hole of the third insulating layer 115c.

Accordingly, signals from the flexible circuit board (or flexible film) 310 (showed in FIG. 2) and the printed circuit board 330 (showed in FIG. 2) may be transmitted to the 2-1th connection line 122a through the 2-4th connection line 122d, the 2-3th connection line 122c, and the 2-2 connection line 122b.

The plurality of first connection lines 121 and the plurality of second connection lines 122 may be formed of a conductive material having excellent ductility or various conductive materials used in the display area AA. For example, the second connection line 122 partially disposed in the bending area BA may be formed of a conductive material having excellent ductility, such as gold (Au), silver (Ag), or aluminum (Al), but implementations of the present disclosure are not limited thereto. For another example, the plurality of first connection lines 121 and a plurality of second connection lines 122 may be formed of molybdenum (Mo), chromium (Cr), titanium (Ti), nickel (Ni), neodymium (Nd), copper (Cu), an alloy of silver (Ag) and magnesium (Mg), or an alloy thereof, but implementations of the present disclosure are not limited thereto.

A third insulating layer 115c may be disposed on the plurality of first connection lines 121 and the plurality of second connection lines 122. The third insulating layer 115c may be disposed in the remaining area except for the bending area BA, but implementations of the present disclosure are not limited thereto. The third insulating layer 115c may be disposed in the display area AA, the first non-display area NA1, and the second non-display area NA2. At least a portion of the third insulating layer 115c in the bending area BA may be removed. The third insulating layer 115c may be formed of an organic insulating material, but implementations of the present disclosure are not limited thereto. For example, the third insulating layer 115c may be formed of a photo resist, polyimide (PI), a photo acryl-based material, or the like, but implementations of the present disclosure are not limited thereto.

A plurality of banks BNK may be disposed on the third insulating layer 115c in the display area AA. The plurality of banks BNK may overlap each of the plurality of sub-pixels. The plurality of banks BNK may not be disposed in the first non-display area NA1, the second non-display area NA2, and the bending area BA. One or more light emitting devices ED of the same type may be disposed on an upper portion of each of the plurality of banks BNK.

In the display area AA, a plurality of signal lines TLs may be disposed on the third insulating layer 115c. The plurality of signal lines TLs may be disposed between the plurality of banks BNK. For example, the plurality of signal lines TLs may be disposed adjacent to one of the plurality of banks BNK. Each of the plurality of signal lines TLs may be electrically connected to the first connection line 121, for example, the 1-4th connection line 121d.

A plurality of contact electrodes CCE may be disposed on the third insulating layer 115c in the display area AA. The plurality of contact electrodes CCE may supply the cathode voltage from the pixel driving circuit PD to the second electrode CE2. Each of the plurality of contact electrodes CCE may be electrically connected to the first connection line 121, for example, the 1-4th connection line 121d.

A first electrode CE1 may be disposed on the bank BNK. For example, the first electrode CE1 may extend from the adjacent signal line TL to an upper portion of the bank BNK. The first electrode CE1 may be disposed on an upper surface of the bank BNK and a side surface of the bank BNK. For example, the first electrode CE1 may extend from the signal line TL on an upper surface of the third insulating layer 115c to the side surface of the bank BNK and the upper surface of the bank BNK. The first electrode CE1 may be integrally formed with the signal line TL.

Referring to FIG. 9, the first electrode CE1 may include a plurality of conductive layers. For example, the first electrode CE1 may include a first conductive layer CE1a, a second conductive layer CE1b, a third conductive layer CE1c, and a fourth conductive layer CE1d, but implementations of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b, and the fourth conductive layer CE1d may be disposed on the third conductive layer CE1c. For example, the first conductive layer CE1a, the second conductive layer CE1b, the third conductive layer CE1c, and the fourth conductive layer CE1d may be formed of titanium (Ti), molybdenum (Mo), aluminum (Al), or titanium (Ti) and indium tin oxide (ITO), but implementations of the present disclosure are not limited thereto.

According to the present disclosure, some of the plurality of conductive layers included in the first electrode CE1 having high reflection efficiency may be composed of an alignment key and/or a reflector for aligning the light emitting device ED. For example, the second conductive layer CE1b among the plurality of conductive layers of the first electrode CE1 may include a reflective material. For example, the second conductive layer CE1b may include aluminum (Al), but implementations of the present disclosure are not limited thereto. Thus, the second conductive layer CE1b may be used as a reflective plate. Due to a high reflection efficiency of the second conductive layer CE1b, identification may be easily performed in a manufacturing process, and thus a position or a transfer position of the light emitting device ED with respect to the second conductive layer CE1b may be arranged.

For example, in order to use the second conductive layer CE1b as the reflective plate, the third conductive layer CE1c and the fourth conductive layer CE1d covering the second conductive layer CE1b may be partially removed or etched. For example, portions of the third and fourth conductive layers CE1c and CE1d disposed on the bank BNK may be removed or etched to expose an upper surface of the second conductive layer CE1b. For example, a central portion and an edge portion of the third and fourth conductive layers CE1c and CE1d on which a solder pattern SDP is disposed may remain, and remaining portions except for the center portion of the third and fourth conductive layers CE1c and CE1d may be removed. For example, the central portion and the edge portion of each of the third conductive layer CE1c made of titanium (Ti) and the fourth conductive layer CE1d made of indium tin oxide (ITO) may not be etched. Thus, other conductive layers of the first electrode CE1 may be prevented from being corroded by a TMAH (Tetra Methyl Ammonium Hydroxide) solution used in a mask process of the first electrode CE1.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has high adhesion to the solder pattern SDP and has corrosion resistance and acid resistance. However, implementations of the present disclosure are not limited thereto.

The first conductive layer CE1a, the second conductive layer CE1b, the third conductive layer CE1c, and the fourth conductive layer CE1d may be sequentially deposited and then patterned by a photolithography process and an etching process, but implementations of the present disclosure are not limited thereto.

As shown in FIGS. 8 and 9, according to the present disclosure, the signal line TL, the contact electrode CCE, and the pad electrode PE disposed on the same layer as the first electrode CE1 may be formed of multiple layers of conductive materials, but implementations of the present disclosure are not limited thereto. For example, the signal line TL, the contact electrode CCE, and the pad electrode PE may be formed of multiple layers in which indium tin oxide (ITO), titanium (Ti), aluminum (Al), and titanium (Ti) are stacked, but implementations of the present disclosure are not limited thereto.

According to the present disclosure, a solder pattern SDP may be disposed on the first electrode CE1 in each of the plurality of sub-pixels. The solder pattern SDP may bond the light emitting device ED to the first electrode CE1. The first electrode CE1 and the light emitting device ED may be electrically connected to each other through eutectic bonding using the solder pattern SDP, but implementations of the present disclosure are not limited thereto. For example, when the solder pattern SDP is formed of indium (In), and the anode electrode 134 of the light emitting device ED is formed of gold (Au), the solder pattern SDP and the anode electrode 134 may be bonded to each other by applying heat and pressure in the transfer process of the light emitting device ED. The light emitting device ED may be bonded to the solder pattern SDP and the first electrode CE1 without a separate adhesive member through eutectic bonding. For example, the solder pattern SDP may be formed of indium (In), tin (Sn), or alloys thereof, but implementations of the present disclosure are not limited thereto. For example, the solder pattern SDP may be a bonding pad, a contact pad, or the like, but implementations of the present disclosure are not limited thereto.

According to an implementation of the present disclosure, the passivation layer 116 may be disposed on the wiring layer. For example, the passivation layer 116 may cover the wiring layer in the display area AA. For example, the passivation layer 116 may be disposed on the plurality of signal lines TL, the plurality of first electrodes CE1, the plurality of contact electrodes CCE, and the third insulation layer 115c. For example, the passivation layer 116 may be disposed in the display area AA, the first non-display area NA1, and the second non-display area NA2. A portion of the passivation layer 116 disposed in the bending area BA may be removed. A portion of the passivation layer 116 covering the plurality of pad electrodes PE may be removed in the second non-display area NA2. A portion of the passivation layer 116 covering the plurality of contact electrodes CCE may be removed in the display area AA. The passivation layer 116 covering the solder pattern SDP may be removed in the display area AA. The passivation layer 116 may cover the first electrode CE1. The passivation layer 116 may cover a portion of the exposed upper surface of the second conductive layer CE1b.

Since the passivation layer 116 covers the remaining areas while exposing a portion of the plurality of pad electrodes PE, a portion of the plurality of contact electrodes CCE and a portion of the solder pattern SDP, penetration of moisture or impurities flowing into the light emitting device ED may be reduced. For example, the passivation layer 116 may be formed of a single layer or multiple layers including silicon oxide (SiOₓ) or silicon nitride (SiNₓ), but implementations of the present disclosure are not limited thereto. For example, the passivation layer 116 may be a protective layer or an insulating layer, but implementations of the present disclosure are not limited thereto. For example, the passivation layer 116 may include a hole exposing the solder pattern SDP and a hole exposing the contact electrode CCE.

In each of the plurality of sub-pixels, the light emitting device ED may be disposed on the solder pattern SDP. The first light emitting device 130 may be disposed in the first sub-pixel SP1. The second light emitting device 140 may be disposed in the second sub-pixel SP2. The third light emitting device 150 may be disposed in the third sub-pixel SP3.

The light emitting device ED may be formed on silicon wafers by means of metal organic vapor deposition (MOCVD), chemical vapor deposition (CVD), plasma-enhanced chemical vapor deposition (PECVD), molecular beam growth (MBE), hydride vapor deposition (HVPE), or sputtering, but implementations of the present disclosure are not limited thereto.

Referring to FIG. 9, the first light emitting device 130 may include an anode 134, a first semiconductor layer 131, an active layer 132, a second semiconductor layer 133, a cathode 135, and an encapsulation layer 136, but implementations of the present disclosure are not limited thereto. For example, the encapsulation layer 136 may not be included in the first light emitting device 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may include a compound semiconductor such as a group III-V or a group II-VI, and may be doped with impurities (or dopants). For example, one of the first semiconductor layer 131 and the second semiconductor layer 133 may be a semiconductor layer doped with n-type impurities, and the other may be a semiconductor layer doped with p-type impurities, but implementations of the present disclosure are not limited thereto. For example, At least one of the first semiconductor layer 131 and the second semiconductor layer 133 may be a layer in which an n-type or p-type impurity is doped into a material such as gallium nitride (GaN), gallium phosphide (GaP), gallium arsenic phosphide (GaAsP), aluminum gallium indium phosphide (AlGalnP), indium aluminum phosphide (InAIP), aluminum gallium nitride (AlGaN), aluminum indium nitride (AlInN), aluminum gallium nitride (AlInGaN), aluminum gallium arsenic (AlGaAs), gallium arsenic (AlGaAs), but implementations of the present disclosure are not limited thereto. For example, the n-type impurity may be silicon (Si), germanium (Ge), selenium (Se), carbon (C), tellurium (Te), tin (Sn), or the like, but implementations of the present disclosure are not limited thereto. For example, the p-type impurity may be magnesium (Mg), zinc (Zn), calcium (Ca), strontium (Sr), barium (Ba), beryllium (Be), or the like, but implementations of the present disclosure are not limited thereto.

For example, each of the first semiconductor layer 131 and the second semiconductor layer 133 may be a nitride semiconductor including the n-type impurity and a nitride semiconductor including the p-type impurity, but implementations of the present disclosure are not limited thereto. For example, the first semiconductor layer 131 may be a nitride semiconductor including the p-type impurity, and the second semiconductor layer 133 may be a nitride semiconductor including the n-type impurity, but implementations of the present disclosure are not limited thereto.

The active layer 132 may be disposed between the first semiconductor layer 131 and the second semiconductor layer 133. The active layer 132 may emit light by receiving holes and electrons from the first semiconductor layer 131 and the second semiconductor layer 133. For example, the active layer 132 may be formed of one of a single well structure, a multi-well structure, a single quantum well structure, a multi-quantum well (MQW) structure, a quantum dot structure, and a quantum line structure, but implementations of the present disclosure are not limited thereto. For example, the active layer 132 may be formed of indium gallium nitride (InGaN), or gallium nitride (GaN), but implementations of the present disclosure are not limited thereto.

For another example, the active layer 132 may include a multi-quantum well (MQW) structure having a well layer and a barrier layer having a band gap higher than that of the well layer. For example, the active layer 132 may include InGaN as a well layer, and may include an AlGaN layer as a barrier layer, but implementations of the present disclosure are not limited thereto.

The anode 134 may be disposed between the first semiconductor layer 131 and the solder pattern SDP. For example, the anode 134 may electrically connect the first semiconductor layer 131 to the first electrode CE1. The anode voltage output from the pixel driving circuit PD may be applied to the first semiconductor layer 131 through the signal line TL, the first electrode CE1, and the anode 134. For example, the anode 134 may be formed of a conductive material capable of eutectic bonding with the solder pattern SDP, but implementations of the present disclosure are not limited thereto. For example, the anode 134 may be formed of gold (Au), tin (Sn), tungsten (W), silicon (Si), silicon (Ag), titanium (Ti), iridium (Ir), chromium (In), indium (Zn), zinc (Pb), lead (Ni), platinum (Pt), copper (Cu), or alloys thereof, but implementations of the present disclosure are not limited thereto.

The cathode 135 may be disposed on the second semiconductor layer 133. For example, the cathode 135 may electrically connect the second semiconductor layer 133 to the second electrode CE2. The cathode voltage output from the pixel driving circuit PD may be applied to the second semiconductor layer 133 through the contact electrode CCE, the second electrode CE2, and the cathode 135. The cathode 135 may be formed of a transparent conductive material to allow light emitted from the light emitting device ED to be directed to an upper portion of the light emitting device ED, but implementations of the present are not limited thereto. For example, the cathode 135 may be formed of a material such as indium tin oxide (ITO), indium zinc oxide (IZO), indium gallium zinc oxide (IGZO), or the like, but implementations of the present disclosure are not limited thereto.

The encapsulation layer 136 may be disposed on at least a portion of each of the first semiconductor layer 131, the active layer 132, the second semiconductor layer 133, the anode 134, and the cathode 135. For example, the encapsulation layer 136 may surround at least a portion of each of the first semiconductor layer 131, the active layer 132, the second semiconductor layer 133, the anode 134, and the cathode 135.

For example, the encapsulation layer 136 may protect the first semiconductor layer 131, the active layer 132, and the second semiconductor layer 133. For example, the encapsulation layer 136 may be disposed on a side surface of the first semiconductor layer 131, a side surface of the active layer 132, and a side surface of the second semiconductor layer 133.

The encapsulation layer 136 may be disposed on at least a portion of the anode 134 and the cathode 135, for example, on the edge portion (or one side) of the anode 134 and the edge portion (or one side) of the cathode 135. At least a portion of the anode 134 may be exposed by the encapsulation layer 136, and the anode 134 may connect with the solder pattern SDP. For example, at least a portion of the cathode 135 may be exposed by the encapsulation layer 136 and the cathode 135 may connect with the second electrode CE2. For example, the encapsulation layer 136 may be formed of an insulating material such as silicon nitride (SiNₓ) or silicon oxide (SiOₓ), but implementations of the present disclosure are not limited thereto.

For another example, the encapsulation layer 136 may have a structure in which a reflective material is distributed in a resin layer, but implementations of the present disclosure are not limited thereto. For example, the encapsulation layer 136 may be manufactured as a reflector having various structures, but implementations of the present disclosure are not limited thereto. Light emitted from the active layer 132 may be reflected upward by the encapsulation layer 136 so that light extraction efficiency may be improved. For example, the encapsulation layer 136 may be a reflective layer, but implementations of the present disclosure are not limited thereto.

According to the present disclosure, the light emitting device ED has been described as a vertical structure, but implementations of the present disclosure are not limited thereto. For example, the light emitting device ED may have a lateral structure or a flip chip structure.

Although the first light emitting device 130 has been described with reference to FIG. 9, the second light emitting device 140 and the third light emitting device 150 may have substantially the same structure as the first light emitting device 130. For example, the second light emitting device 140 and the third light emitting device 150 may have substantially the same configuration as the first semiconductor layer 131, the active layer 132, the second semiconductor layer 133, the anode 134, the cathode 135, and the encapsulation layer 136.

As can be seen from FIGS. 8 and 9, the display device 1000 according to an implementation of the present disclosure may further include optical layers (or light diffusion layers) 117a, 117b, and 117c.

The optical layers 117a and 117b may surround the plurality of light emitting devices ED in the display area AA. For example, the optical layers 117a and 117b may cover the plurality of light emitting devices ED in the display area AA.

According to an implementation of the present disclosure, a first optical layer 117a surrounding the plurality of light emitting devices ED may be disposed in the display area AA. For example, the first optical layer 117a may cover the side surfaces of the plurality of light emitting devices ED and the side surfaces of the plurality of banks BNK in the plurality of sub-pixels. For example, the first optical layer 117a may cover a portion of the passivation layer 116. For example, the first optical layer 117a may cover the second electrode CE2, a portion of the passivation layer 116, and an area between the plurality of light emitting devices ED. The first optical layer 117a may be disposed or covered between the plurality of light emitting devices ED and between the plurality of banks BNK included in one pixel PX. For example, the first optical layer 117a may extend in the row direction (or the first direction X), and the plurality of first optical layers 117a may be spaced apart from each other in the column direction (or the second direction Y). For example, the first optical layer 117a may be disposed between the passivation layer 116 and the second electrode CE2 to surround the side surface of the light emitting device ED and the side surface of the bank BNK, but implementations of the present disclosure are not limited thereto. For example, the first optical layer 117a may be a diffusion layer, a sidewall diffusion layer, or the like, but implementations of the present disclosure are not limited thereto

The first optical layer 117a may include an organic insulating material in which fine particles 117ap distributed, but implementations of the present disclosure are not limited thereto. For example, the first optical layer 117a may be formed of siloxane in which fine metal particles 117ap such as titanium dioxide (TiO₂) particles are distributed, but implementations of the present distributed are not limited thereto. Light from the plurality of light emitting devices ED may be scattered by fine particles 117ap distributed in the first optical layer 117a and emitted to an outside of the display panel 100. Accordingly, the first optical layer 117a may improve extraction efficiency of light emitted from the plurality of light emitting devices ED.

For example, the first optical layer 117a may be disposed in each of the plurality of pixels PX or may be disposed in some pixels PX disposed in the same row, but implementations of the present disclosure are not limited thereto. For example, the first optical layer 117a may be disposed in each of the plurality of pixels PX, or the plurality of pixels PX may share one first optical layer 117a. For another example, each of the plurality of sub-pixels may separately include a first optical layer 117a, but implementations of the present disclosure are not limited thereto.

According to the present disclosure, the second optical layer 117b may be disposed on the passivation layer 116 in the display area AA. For example, the second optical layer 117b may surround the first optical layer 117a. For example, the second optical layer 117b may be in contact with a side surface of the first optical layer 117a. For example, the second optical layer 117b may be disposed in an area between the plurality of pixels PX (or non-emission area). However, implementations of the present disclosure are not limited thereto. For example, the second optical layer 117b may be a diffusion layer, a window diffusion layer, or the like, but implementations of the present disclosure are not limited thereto.

The second optical layer 117b may be formed of an organic insulating material, but implementations of the present disclosure are not limited thereto. The second optical layer 117b may be formed of the same material as the first optical layer 117a, but implementations of the present disclosure are not limited thereto. For example, the first optical layer 117a may include fine particles, and the second optical layer 117b may not include fine particles. For example, the second optical layer 117b may be formed of siloxane, but implementations of the present disclosure are not limited thereto.

A thickness of the first optical layer 117a may be less than a thickness of the second optical layer 117b, but implementations of the present disclosure are not limited thereto. For example, an upper surface of the second optical layer 117b may be formed of a flat surface, and an upper surface of the first optical layer 117a may be formed of a concave curved surface. Accordingly, in a plan view, an area in which the first optical layer 117a is disposed may include a concave portion recessed from the upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 may be disposed on the plurality of light emitting devices ED. For example, the second electrode CE2 may include a transparent conductive oxide such as indium tin oxide (ITO) or indium zinc oxide (IZO), but implementations of the present disclosure are not limited thereto. For example, the second electrode CE2 may be in contact with the cathode 135. For example, the second electrode CE2 may overlap the entire first optical layer 117a, and may overlap a portion of the second optical layer 117b. For example, the second electrode CE2 may be electrically connected to the contact electrode CCE through the second optical layer 117b. For example, the second electrode CE2 may be electrically connected to the contact electrode CCE through a contact hole formed in the second optical layer 117b.

The second electrode CE2 may extend continuously in the row direction (or the first direction X) of the substrate 110. Accordingly, the second electrode CE2 may be connected in common to the plurality of light emitting devices ED in each of a plurality of pixels PX arranged in the row direction (or the first direction X) of the substrate 110.

According to the present disclosure, the second electrode CE2 may continuously extend on the first optical layer 117a, the second optical layer 117b, and the light emitting device ED. The area in which the first optical layer 117a is disposed may include the concave portion recessed from the upper surface of the second optical layer 117b. Accordingly, since a first portion of the second electrode CE2 disposed on the first optical layer 117a is disposed along the concave portion, the first portion may be disposed at a lower position than a second portion of the second electrode CE2 disposed on the second optical layer 117b. For example, the thickness of the first optical layer 117a may decrease from the second optical layer 117b to a center of the first optical layer 117a for electrical connection (or contact) between each of the first to third light emitting devices 130, 140, and 150 and the second electrode CE2.

The third optical layer 117c may be disposed on the second electrode CE2. The third optical layer 117c may overlap the plurality of light emitting devices ED and the first optical layer 117a. For example, the third optical layer 117c may not overlap the second optical layer 117b. Since the third optical layer 117c is disposed on the second electrode CE2 and the plurality of light emitting devices ED, spot (or mura) that may occur in some of the plurality of light emitting devices ED may be improved. For example, when the plurality of light emitting devices ED are transferred on the substrate 110 of the display panel 100, a region in which a gap between the plurality of light emitting devices ED is not uniform due to a process deviation, or the like may be formed. When the gap between the plurality of light emitting devices ED is not uniform, a light emitting area of each of the plurality of light emitting devices ED may be non-uniformly disposed, and thus a spot (or mura) may be recognized by a user. Accordingly, since the third optical layer 117c for uniformly diffusing light on an upper portion of the plurality of light emitting devices ED is formed, it is possible to reduce visibility of light emitted from some light emitting devices ED as spots (or mura). Therefore, since the light emitted from the plurality of light emitting devices ED is uniformly diffused by the third optical layer 117c and extracted to the outside of the display panel 100, the luminance uniformity of the display device may be improved.

The third optical layer 117c may be formed of an organic insulating material in which fine particles 117cp are distributed, but implementations of the present disclosure are not limited thereto. For example, the third optical layer 117c may be formed of siloxane in which fine metal particles 117cp such as titanium dioxide (TiO₂) particles are distributed, but implementations of the present disclosure are not limited thereto. For example, the third optical layer 117c may be formed of the same material as the first optical layer 117a, but implementations of the present disclosure are not limited thereto. For example, the third optical layer 117c may be a diffusion layer, an upper diffusion layer, or the like, but implementations of the present disclosure are not limited thereto.

According to the present disclosure, light from the plurality of light emitting devices ED may be scattered by fine particles 117cp distributed in the third optical layer 117c and emitted to the outside of the display panel 100. The third optical layer 117c may evenly mix the light emitted from the plurality of light emitting devices ED to further improve luminance uniformity of the display device. In addition, light extraction efficiency of the display device may be improved by the light scattered from the plurality of fine particles 117cp, and thus the display device may be driven at a low power.

In the display area AA, a black matrix BM may be disposed on the second electrode CE2, the first optical layer 117a, the second optical layer 117b, and the third optical layer 117c. For example, the black matrix BM may fill a contact hole of the second optical layer 117b. Since the black matrix BM may cover the display area AA, color mixture of light of the plurality of sub pixels and reflection of external light may be reduced. For example, since the black matrix BM is disposed within a contact hole in which the second electrode CE2 and the contact electrode CCE are connected, light leakage between the plurality of adjacent sub-pixels may be prevented. For example, the black matrix BM may be formed of an opaque material, but implementations of the present disclosure are not limited thereto. For example, the black matrix BM may be an organic insulating material to which a black pigment or a black dye is added, but implementations of the present disclosure are not limited thereto.

Referring to FIG. 8, the display device 1000 according to an implementation of the present disclosure may further include a cover layer 118.

The cover layer 118 may cover the display area AA. For example, the cover layer 118 may be disposed on the black matrix BM in the display area AA. The cover layer 118 may protect a plurality of light emitting devices ED. For example, components between the substrate 110 and the cover layer 118 may be protected by the substrate 110 and the cover layer 118. For example, the cover layer 118 may be formed of an organic insulating material, but implementations of the present disclosure are not limited thereto. For example, the cover layer 118 may be formed of a photo resist, polyimide (PI), a photo acryl-based material, or the like, but implementations of the present disclosure are not limited thereto. For example, the cover layer 118 may be an overcoating layer, an insulating layer, or the like, but implementations of the present disclosure are not limited thereto.

A polarizing layer 180 may be disposed on the cover layer 118 via a first adhesive layer 181. A cover member 120 may be disposed on the polarizing layer 180 via a second adhesive layer 185. For example, the touch panel 200 may be disposed between the polarizing layer 180 and the second adhesive layer 185. The polarizing layer 180 may be connected (or attached) to a rear surface of the touch panel 200 via a third adhesive layer 187. The touch panel 200 may be connected (or attached) to the rear surface of the cover member 120 via the second adhesive layer 185. For example, each of the first adhesive layer 181, the second adhesive layer 185, and the third adhesive layer 187 may include an optically clear adhesive (OCA), an optically clear resin (OCR), a pressure sensitive adhesive (PSA) or the like, but implementations of the present disclosure are not limited thereto.

According to the present disclosure, the plurality of pad electrodes PE may be disposed on the third insulating layer 115c in the second non-display area NA2. For example, a portion of the plurality of pad electrodes PE may be exposed by the passivation layer 116. For example, the plurality of pad electrodes PE may be electrically connected to the 2-4th connection line 122d through a contact hole of the third insulating layer 115c.

An adhesive film ACF may be disposed on the plurality of pad electrodes PE. The adhesive film ACF may be an adhesive layer in which conductive balls are distributed in an insulating material, but implementations of the present disclosure are not limited thereto. When heat or pressure is applied to the adhesive film ACF, the conductive ball may have conductive characteristics in a region to which heat or pressure is applied. An adhesive film ACF may be disposed between the plurality of pad electrodes PE and the flexible circuit board (or flexible film) 310, so that a flexible circuit board (or flexible film) 310 may be attached to or bonded to the plurality of pad electrodes PE. For example, the adhesive film ACF may be an anisotropic conductive film (ACF), but implementations of the present disclosure are not limited thereto.

The flexible circuit board (or flexible film) 310 may be disposed on the adhesive film ACF. The flexible circuit board (or flexible film) 310 may be electrically connected to the plurality of pad electrodes PE through the adhesive film ACF. Therefore, signals output from the flexible circuit board (or flexible film) 310 and the printed circuit board 330 may be transmitted to the pixel driving circuit PD of the display area AA through the wiring layer. For example, signals output from the flexible circuit board (or flexible film) 310 and the printed circuit board 330 may be transmitted to the pixel driving circuit PD of the display area AA through the plurality of pad electrodes PE, the 2-4th connection line 122d, the 2-3th connection line 122c, the 2-2th connection line 122b, and the 2-1th connection line 122a.

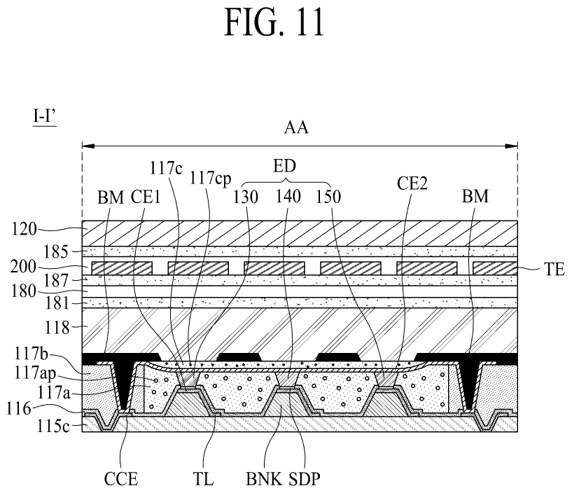

FIG. 10 is a diagram illustrating driving timing of the display panel 100 and the touch panel 200 according to an implementation of the present disclosure.

Referring to FIG. 10, the display device may be driven according to a display period Display_Tn and a touch period Touch_Tn. The display period Display_Tn may be the period in which the display panel 100 is driven, and the touch period Touch_Tn may be the period in which the touch panel 200 is driven.

In this case, the display period Display_Tn and the touch period Touch_Tn may be the same. That is, the display panel 100 and the touch panel 200 may be simultaneously driven. Accordingly, the display device may recognize a user's touch through the touch panel 200 while displaying a screen through the display panel 100.

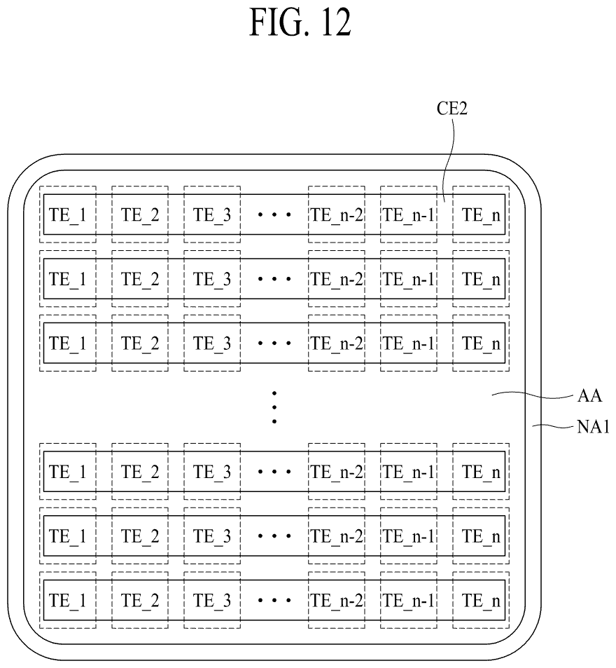

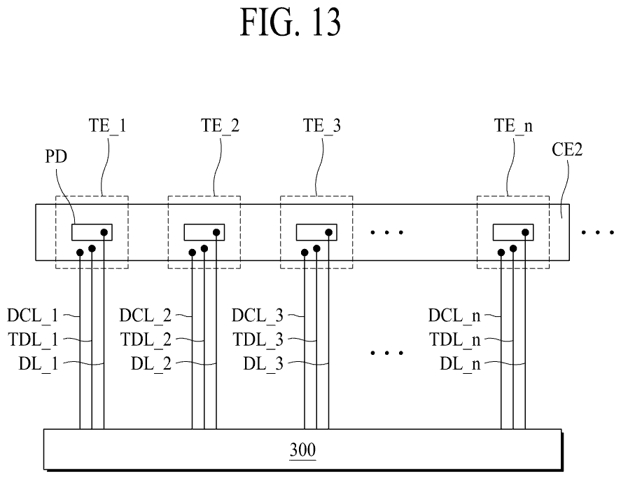

FIG. 11 is an enlarged view of a display device according to an implementation of the present disclosure. FIG. 12 is a plan view of a display device according to an implementation of the present disclosure.

Referring to FIG. 11, the touch panel 200 may include a plurality of touch electrodes TE. The plurality of touch electrodes TE may be disposed on the second electrode CE2.

Referring to FIG. 12, FIG. 12 illustrates a second electrode CE2 of the display panel 100 and a plurality of touch electrodes TE of the touch panel 200. As described above, the second electrode CE2 has a width corresponding to one row (or horizontal line) and may extend in a column direction (or the first direction X).

The plurality of touch electrodes TE may overlap the second electrode CE2. FIG. 12 illustrates that n touch electrodes TE are disposed in each of the plurality of second electrodes CE2, but is not limited thereto.

As described above, the plurality of touch electrodes TE may include an electrode structure corresponding to a mutual-capacitance type configured to cross a plurality of touch driving electrodes and a plurality of touch sensing electrodes. Alternatively, the plurality of touch electrodes TE may include an electrode structure corresponding to a self-capacitance type composed of only a plurality of touch sensing electrodes. FIG. 12 illustrates an electrode structure corresponding to the self-capacitance type.

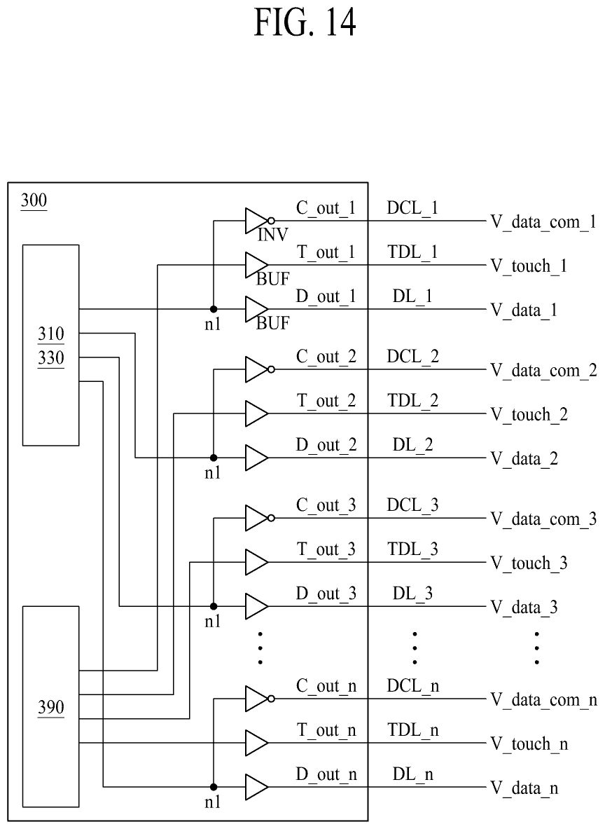

FIG. 13 is a plan view of a display device according to an implementation of the present disclosure. In detail, FIG. 13 illustrates an electrical connection relationship between the plurality of touch electrodes TE, the plurality of pixel driving circuits PD, and the driving circuit unit 300.

FIG. 13 discloses that the plurality of pixel driving circuits PD are provided to correspond to each of the plurality of touch electrodes TE, but are not limited thereto.

As described above in FIGS. 2 and 3, the driving circuit unit 300 may include a flexible circuit board (or flexible film) 310, a printed circuit board 330, and a touch IC 390. The flexible circuit board (or flexible film) 310 and the printed circuit board 330 may supply a signal to each of the plurality of pixel driving circuits PD through a plurality of driving lines VL. The touch IC 390 may supply a touch driving signal to the plurality of touch electrodes TE.

In FIG. 13, the structure of the flexible circuit board (or flexible film) 310, the printed circuit board 330, and the touch integrated circuit 390 is omitted, and the driving circuit unit 300 is shown.

The driving circuit unit 300 may be electrically connected to the plurality of pixel driving circuits PD through a plurality of data lines DL. In addition, the driving circuit unit 300 may be electrically connected to the plurality of touch electrodes TE through a plurality of touch driving lines TDL and a plurality of data compensation lines DCL. In addition, the plurality of driving lines VL described in FIGS. 2 and 3 may include the plurality of data lines DL.

The plurality of touch driving lines TDL may include a first touch driving line TDL_1 to an n-th touch driving line TDL_n. In addition, the plurality of data lines DL may include a first data line DL_1 to an n-th data line DL_n. In addition, the plurality of data compensation lines may include a first data compensation line DCL_1 to an n-th data compensation line DCL_n.

FIG. 14 is a block diagram of a display device according to an implementation of the present disclosure. Specifically, FIG. 14 illustrates various signals applied from the driving circuit unit 300.

Referring to FIG. 14, a flexible circuit board (or a flexible film) 310 and a printed circuit board 330 may generate a data signal V_data.

The data signal V_data generated by the flexible circuit board (or flexible film) 310 and the printed circuit board 330 may be applied to a buffer BUF. The data signal V_data stabilized by the buffer BUF may be applied to the data signal output line D_out. Each of the plurality of data signal output lines D_out may be electrically connected to the plurality of data lines DL. Accordingly, the data signal V_data may be supplied to the plurality of pixel driving circuits PD through the plurality of data lines DL.

In addition, the data signal V_data generated by the flexible circuit board (or flexible film) 310 and the printed circuit board 330 may be applied to an inverter INV through a first node n1. The data signal V_data of which the phase is changed by the inverter INV may be applied to a data compensation signal output line C_out. In this case, the data signal V_data of which the phase is changed may be specified as a data compensation signal V_data_com. In particular, the data compensation signal V_data_com may be an inverse phase signal of the data signal V_data.

Each of the plurality of data compensation signal output lines C_out may be electrically connected to the plurality of data compensation lines DCL. Accordingly, the data compensation signal V_data_com may be supplied to the plurality of touch electrodes TE through the plurality of data compensation lines DCL.

The touch IC 390 may generate a touch driving signal V_touch. The touch driving signal V_touch generated by the touch IC 390 may be applied to the buffer BUF. The touch driving signal V_touch stabilized by the buffer BUF may be applied to the touch signal output line T_out. Each of the plurality of touch signal output lines T_out may be electrically connected to the plurality of touch driving lines TDL. Accordingly, the touch driving signal V_touch may be supplied to the plurality of touch electrodes TE through the plurality of touch driving lines TDL.

The data compensation signal V_data_com may compensate for noise caused by the data signal V_data. Specifically, when the data signal V_data is applied to the plurality of data lines DL, the data signal V_data may affect the plurality of touch driving lines TDL adjacent to the plurality of data lines DL. Accordingly, a first noise occurs in the plurality of touch driving lines TDL due to the data signal V_data, and the touch driving signal V_touch may not be stably applied to the touch electrode TE.

To solve this problem, the present disclosure discloses the plurality of data compensation lines DCL for applying the data compensation signal V_data_com which is the inverse phase signal of the data signal V_data. Like the data signal V_data, a second noise may be generated in the plurality of touch driving lines TDL by the data compensation signal V_data_com. In this case, since the data signal V_data and the data compensation signal V_data_com have opposite phases to each other, the first noise and the second noise may also have opposite phases to each other. Accordingly, the first noise and the second noise may be offset out from each other. Accordingly, noise caused by the data signal V_data may be offset through the data compensation signal V_data_com.

Accordingly, the touch panel 200 may be stably driven by preventing voltage fluctuations of the touch electrode TE.

FIG. 14 shows that the buffer BUF and the inverter INV are formed inside the driving circuit unit 300, but is not limited thereto. For example, the buffer BUF and the inverter INV may be formed outside the driving circuit unit 300. In this case, a phase of the data signal V_data output from the driving circuit unit 300 is changed through the inverter INV formed outside the driving circuit unit 300 and the data signal V_data of which the phase changes may be used as the data compensation signal V_data_com.

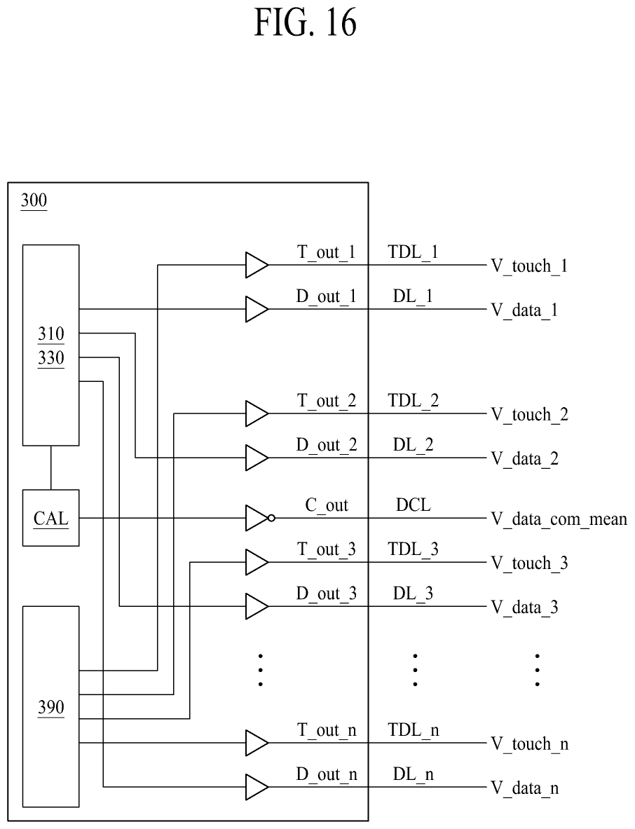

FIG. 15 is a waveform diagram illustrating an example of a driving pulse according to FIG. 14. FIG. 15 illustrates a data signal V_data and a data compensation signal V_data_com.

Referring to FIG. 15, the data signal V_data may include a data driving pulse P_data. In addition, the data compensation signal V_data_com may include a data compensation driving pulse P_data_com.

As described above, the data compensation signal V_data_com may be an inverse phase signal of the data signal V_data. That is, the phase of the data compensation driving pulse P_data_com may be a signal in which the phase of the data driving pulse P_data is delayed by 180°. In addition, the data driving pulse P_data and the data compensation driving pulse P_data_com may have the same frequency and may have the same magnitude of the voltage V_high.

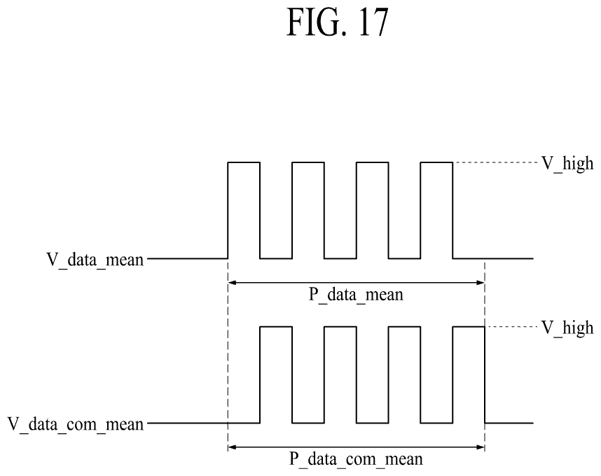

FIG. 16 is a block diagram of a display device according to another implementation of the present disclosure.

Compared with FIG. 14, the driving circuit unit 300 may further include an average data signal calculator CAL.

The average data signal calculator CAL may receive a plurality of data signals V_data from the flexible circuit board (or flexible film) 310 and the printed circuit board 330. The average data signal calculator CAL may receive all of the plurality of data signals V_data supplied to the plurality of pixel driving circuits PD. Alternatively, the average data signal calculator CAL may receive the plurality of data signals V_data supplied to some of the plurality of pixel driving circuits PD.

The average data signal calculator CAL may generate an average data signal V_data_mean through the plurality of data signals V_data supplied from the flexible circuit board (or flexible film) 310 and the printed circuit board 330. The average data signal V_data_mean may be an effective value (RMS, Root Mean Square) of the plurality of data signals V_data.

The average data signal V_data_mean generated by the average data signal calculator CAL may be applied to the inverter INV. The average data signal V_data_mean of which the phase is changed by the inverter INV may be applied to the data compensation signal output line C_out. In this case, the average data signal V_data_mean of which the phase is changed may be specified as an average data compensation signal V_data_com_mean. In particular, the average data compensation signal V_data_com_mean may be an inverse phase signal of the average data signal V_data_mean.

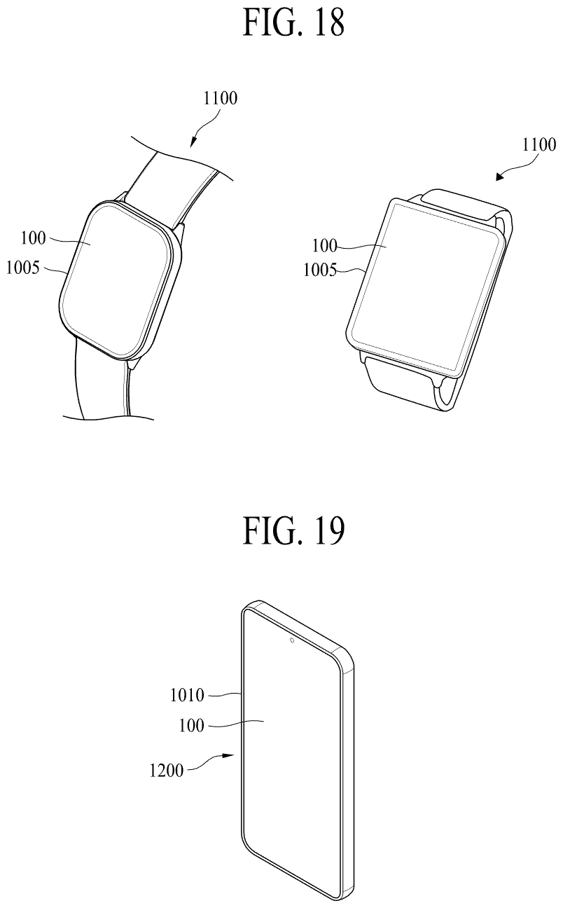

Like the data compensation signal V_data_com_mean described above in FIG. 14, the average data compensation signal V_data_com_mean may compensate for noise caused by the data signal V_data. Although the plurality of data compensation lines DCL corresponding to each of the plurality of data lines DL are formed in FIG. 14, one data compensation line DCL is disclosed in FIG. 17. Accordingly, compared with FIG. 14, the number of wirings may be reduced and a circuit may be simplified.

FIG. 17 discloses one average data signal calculator CAL and one data compensation line DCL, but is not limited thereto. For example, the plurality of data lines DL may be divided into a plurality of regions, and an average value of the data signal V_data in each region may be calculated. And, a plurality of data compensation lines DCL corresponding to each region may be formed to supply the average data compensation signal V_data_com_mean to the touch electrode TE.

FIG. 17 is a waveform diagram illustrating an example of a driving pulse according to FIG. 16. FIG. 16 illustrates an average data signal V_data_mean and an average data compensation signal V_data_com_mean.

Referring to FIG. 17, the average data signal V_data_mean may include an average data driving pulse P_data_mean. In addition, the average data compensation signal V_data_com_mean may include the average data compensation driving pulse P_data_com_mean.

As described above, the average data compensation signal V_data_com_mean may be an inverse phase signal of the average data signal V_data_mean. That is, the phase of the average data compensation driving pulse P_data_com_mean may be a signal in which the phase of the average data driving pulse P_data_mean is delayed by 180°. In addition, the average data driving pulse P_data_mean and the average data compensation driving pulse P_data_com_mean may have the same frequency and may have the same magnitude of voltage V_high.

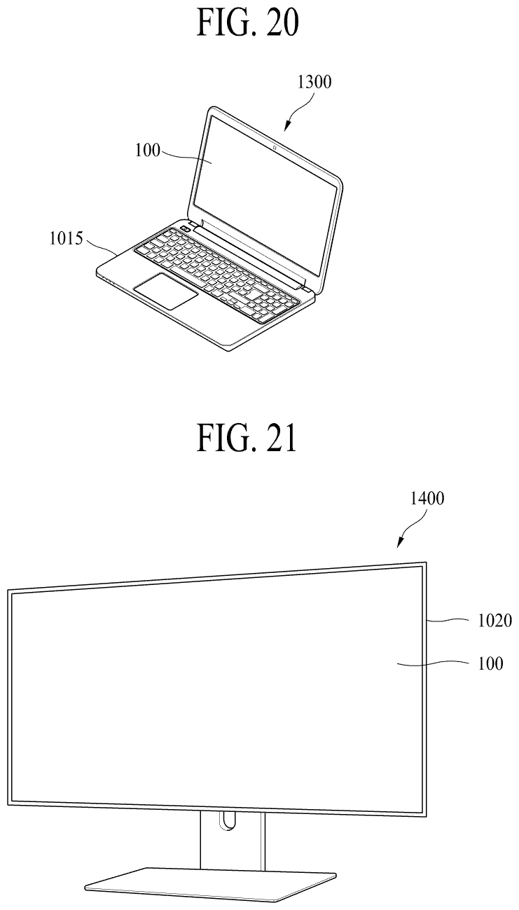

FIGS. 18 to 21 are diagrams illustrating devices to which a display device according to implementations of the present disclosure is applied.

Referring to FIGS. 18 to 21, the display device according to implementations of the present disclosure may be included in various devices or electronic devices. For example, various electronic devices may include a wearable device 1100 as shown in FIG. 18, a mobile device 1200 as shown in FIG. 19, a laptop 1300 as shown in FIG. 20, and a monitor or TV 1400 as shown in FIG. 21, but implementations of the present disclosure are not limited thereto.

Each of the wearable device 1100, the mobile device 1200, the laptop 1300, and the monitor or TV 1400 may include a case unit 1005, 1010, 1015, and 1020 and a display panel 100 and a display device 1000 according to the above-described implementations of the present disclosure.

For example, the display device according to an implementation of the present disclosure includes a mobile device, a video phone, a smart watch, a watch phone, a wearable device, a foldable device, a rollable device, a bendable device, a flexible device, a curved device, a sliding device, a variable device, an electronic notebook, an electronic book, a portable multimedia player (PMP), PDA (personal digital assistant), an MP3 player, a mobile medical device, a desktop PC, a laptop PC, a netbook computer, a workstation, a navigation, a vehicle display, a theater display, a television, a wall paper device, a signage device, a game device, a laptop, a game device, a monitor, a camera, a camcorder or a home appliance.

It will be apparent to those skilled in the art that the present disclosure described above is not limited by the above-described implementations and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device comprising:
a display panel including a plurality of pixel driving circuits;
a touch panel disposed on the display panel and including a plurality of touch electrodes; and
a driving circuit unit electrically connected to the display panel and the touch panel,
wherein the driving circuit unit is configured to supply a plurality of data signals to the plurality of pixel driving circuits,
wherein the driving circuit unit is configured to supply a data compensation signal to the plurality of touch electrodes, and
wherein the data compensation signal and the plurality of data signals have opposite phases to each other.

2. The display device of claim 1, wherein the driving circuit unit includes:
a circuit board configured to generate the plurality of data signals; and
a buffer and an inverter configured to receive the plurality of data signals from the circuit board respectively.

3. The display device of claim 2, wherein a first end of the buffer is connected to the circuit board, and a second end of the buffer is connected to a data signal output line, and
wherein a first end of the inverter is connected to the circuit board, and a second end of the inverter is connected to a data compensation signal output line.

4. The display device of claim 3, wherein the inverter changes a phase of a data signal in the plurality of data signals to output the data compensation signal.

5. The display device of claim 1, wherein the driving circuit unit includes:
a circuit board configured to generate the plurality of data signals; and
an average data signal calculator configured to receive the plurality of data signals from the circuit board,
wherein the average data signal calculator outputs an average data signal through the plurality of data signals, and
wherein the average data signal is an effective value of the plurality of data signals.

6. The display device of claim 5, wherein the driving circuit unit further include a buffer and an inverter,
wherein a first end of the buffer is connected to the circuit board, and a second end of the buffer is connected to a data signal output line, and
wherein a first end of the inverter is connected to the average data signal calculator, and a second end of the inverter is connected to a data compensation signal output line.

7. The display device of claim 6, wherein the inverter changes a phase of the average data signal to output the data compensation signal.

8. The display device of claim 1, wherein the driving circuit unit is electrically connected to the plurality of pixel driving circuits through a data line, and
wherein the driving circuit unit is electrically connected to the plurality of touch electrodes through a data compensation line.

9. The display device of claim 8, wherein the driving circuit unit supplies the data signal to the plurality of pixel driving circuits through the data line, and
wherein the driving circuit unit supplies the data compensation signal to the plurality of touch electrodes through the data compensation line.

10. The display device of claim 8, wherein the display panel includes:
a display area disposed with the plurality of pixel driving circuits;
a first non-display area disposed at a first side of the display area;
a bending area disposed at a first side of the first non-display area; and
a second non-display area disposed at a first side of the bending area and disposed with pad part,
wherein the pad part is electrically connected to the driving circuit unit.

11. The display device of claim 10, further comprising a plurality of link lines extending from the pad part to the bending area and the first non-display area, and
wherein the plurality of link lines are electrically connected to a plurality of driving lines disposed in the display area, and
wherein the plurality of driving lines are electrically connected to the plurality of pixel driving circuits.

12. The display device of claim 11, wherein the plurality of driving lines include the data line.

13. The display device of claim 1, wherein the driving circuit unit includes a touch IC that generates a touch driving signal, and
wherein the driving circuit unit supplies the touch driving signal to the plurality of touch electrodes through a touch driving line.

14. The display device of claim 1, wherein the display panel and the touch panel are driven at a same time.
